(19) United States
(12) Patent Application Publication
(10) Pub. No.: US 2026/0344333 A1
(43) Pub. Date: Oct. 29, 2026

(54) SUBSTRATE TREATMENT APPARATUS

(71) Applicant: SCREEN Holdings Co., Ltd., Kyoto (JP)

(72) Inventors: Yuichi TAKAYAMA, Kyoto (JP); Hiroyuki YASHIKI, Kyoto (JP); Kota TANIKAWA, Kyoto (JP); Koji OTAWA, Kyoto (JP)

(21) Appl. No.: 19/123,061

(22) PCT Filed: Oct. 24, 2022
(86) PCT No.: PCT/JP2022/039534

§ 371 Date: Apr. 21, 2025

(51) Int. Cl. H10P 72/00; G03F 7/42

(52) U.S. Cl. CPC H10P 72/0421; G03F 7/422; H10P 72/0448

(57) ABSTRACT

A controller of the present invention supplies an ozone gas into a chamber in a state where a first control valve is opened and a second control valve is closed to treat a substrate, and then closes the first control valve and opens the second control valve to cause suction by a suction pipe when supplying an inert gas into the chamber. Therefore, a first filter in which the ozone gas remains and a first control valve in which particles are likely to be generated are sucked through the suction pipe. Therefore, in a first pipe, no gas flows from a second branch point to the chamber side. As a result, since the ozone gas can be prevented from being mixed into the inert gas to the chamber side, the replacement of the ozone gas can be performed in a short time, and contamination by particles can be prevented.

### TECHNICAL FIELD

The present invention, the present invention relates to a substrate treatment apparatus that performs predetermined treatment on a substrate (hereinafter, it is simply referred to as a substrate) such as a semiconductor wafer, a substrate for a liquid crystal display or an organic electroluminescence (EL) display device, a glass substrate for a photomask, a substrate for an optical disk, a substrate for a magnetic disk, a ceramic substrate, or a substrate for a solar cell.

### BACKGROUND ART

In order to form a pattern on the substrate, for example, a photoresist film is deposited on the substrate and patterned, and then etching treatment is performed using the photoresist film on which the pattern is formed as a mask. The photoresist film is then removed because the mask is no longer needed. For removing the photoresist film, for example, a sulfuric hydrogen peroxide mixture (SPM), which is a mixed solution of sulfuric acid and hydrogen peroxide water, is used. The SPM has a strong oxidizing force, and the photoresist film is peeled off and removed from the surface of the substrate. However, for example, when ion implantation is performed on the photoresist film, the surface of the photoresist film is cured. Therefore, in the treatment by supplying only the SPM, the consumption of the SPM increases. In addition, the photoresist film may not be satisfactorily removed only by the SPM.

Therefore, before the supply of the SPM, ozone gas (O₃ gas) is supplied to the photoresist film, and treatment is performed by the oxidizing power thereof. As a result, oxidation (ashing) of the surface of the photoresist film cured by ion implantation becomes possible, and peeling of the photoresist film at the time of subsequent treatment with the SPM becomes easy. As a result, the consumption amount of the SPM can be suppressed.

As an apparatus for treating a substrate by supplying ozone gas as described above, there is an apparatus including a supply mechanism for supplying SPM, nitrogen gas, pure water, and ozone gas to a treatment surface of a substrate by switching (See, for example, Patent Literature 1). In this apparatus, an ozone gas supply source that supplies an ozone gas while generating ozone gas is connected to communicate with the supply mechanism. This apparatus includes a suction mechanism that sucks various gases such as an ozone gas from a treatment space in which a substrate is disposed and discharges the gases to the outside of the apparatus.

In such an apparatus, after the treatment with the ozone gas, the ozone gas in the chamber is replaced with the nitrogen gas before the substrate is transported out of the chamber to perform the treatment with the SPM. Therefore, there is a supply mechanism configured as follows.

There is a “first configuration” including a first pipe, a second pipe, a first filter, a first control valve, a second control valve, and a second filter. One end side of the first pipe is communicatively connected to a chamber, and the other end side thereof is communicatively connected to an ozone gas supply source. One end side of the second pipe is communicatively connected to a branch point which is a part of the first pipe, and the other end side thereof is communicatively connected to a nitrogen gas supply source. The first filter is provided in the first pipe located on the chamber side from the branch point. The first control valve is provided on the ozone supply source side of the branch point, and controls flow of ozone gas in the first pipe. The second control valve is provided on the branch point side in the second pipe and controls flow of nitrogen gas. The second filter is provided on the nitrogen gas supply source side of the second control valve in the second pipe.

In addition, in an apparatus that performs treatment using an ozone gas, for example, there is an apparatus in which a chamber that closes a treatment space for treating a substrate includes a recessed lower lid member that supports a lower portion of a holding mechanism that holds the substrate, and an upper lid member that is configured to be raised and lowered at an upper portion of the holding mechanism and covers the lower lid member during treatment. In the apparatus having such a configuration, in order to prevent a harmful ozone gas from leaking to the surroundings, the inside of the chamber is sucked by a suction mechanism before the treatment of an ozone gas to increase the degree of sealing of the chamber, and suction is generally maintained even during the treatment of an ozone gas.

### CITATION LIST

### Patent Literature

Patent Literature 1: JP 2008-66400 A

### SUMMARY OF INVENTION

### Technical Problem

However, the conventional example having such a configuration has the following problems.

That is, according to the conventional first configuration, the branch point is provided on the upstream side of the first filter. Therefore, an ozone gas also passes through the first filter of nitrogen gas. Therefore, when the replacement is performed by supplying the nitrogen gas from the second pipe after the treatment of the ozone gas, the ozone gas remaining in the first filter is mixed into the nitrogen gas supplied to the chamber. Therefore, there is a problem that the concentration of ozone gas is hardly reduced, and replacement with nitrogen gas takes time.

Therefore, it is conceivable to adopt the following “second configuration”.

One end side of the second pipe is communicatively connected to a branch point which is a part of the first pipe on the chamber side, and the other end side thereof is communicatively connected to a nitrogen gas supply source. The first control valve and the first filter are provided in this order from the branch point toward the ozone supply source. The second filter and the second control valve are provided in this order from the branch point toward the nitrogen gas supply source.

According to such a second configuration, there is no first filter from the branch point to the chamber. Therefore, no inconvenience occurs in the first configuration. However, since the first control valve is provided on the chamber side of the first filter, particles generated in the first control valve may be sucked into the flow of the nitrogen gas flowing from the branch point to the chamber side, and contaminate the substrate in the chamber.

In addition, the conventional example having such a configuration has the following problems.

That is, in the conventional apparatus, for example, about 2 minutes is required from the time point when the generation of the ozone gas is started in the ozone gas supply source until the ozone gas having a predetermined concentration necessary for the treatment is supplied. Therefore, since there is a waiting time until the treatment with an ozone gas is started, it is difficult to shorten the treatment time with an ozone gas, and there is a problem that the throughput cannot be improved.

Furthermore, the conventional example having such a configuration has the following problems.

That is, since the conventional apparatus has only one suction mechanism, the suction force is set to a predetermined pressure. Therefore, when the substrate is treated with the ozone gas while supplying the ozone gas to the chamber, a large amount of ozone gas is also exhausted. Therefore, there is a problem that the consumption of ozone gas increases.

The present invention has been made in view of such circumstances, and an object thereof is to provide a substrate treatment apparatus capable of replacing an ozone gas in a short time and preventing contamination by particles.

The present invention has been made in view of such circumstances, and an object thereof is to provide a substrate treatment apparatus capable of shortening the treatment time with an ozone gas and improving the throughput.

The present invention has been made in view of such circumstances, and an object thereof is to provide a substrate treatment apparatus capable of suppressing consumption of ozone gas while preventing leakage of ozone gas.

### Solution to Problem

In order to achieve such an object, the present invention has the following configuration.

That is, the invention according to claim 1 is a substrate treatment apparatus that performs treatment of removing a film deposited to a substrate, the substrate treatment apparatus including: a chamber that accommodates a substrate and forms a sealed treatment space; a holding mechanism that holds the substrate in the chamber; an ozone gas supply source that supplies an ozone gas having a treatment concentration for treating the substrate; a first pipe that communicatively connects the chamber and the ozone gas supply source; a first control valve that is provided in the first pipe and controls flow of ozone gas in the first pipe; a first filter that is provided in the first pipe on a side closer to the chamber than the first control valve; a second pipe having one end side communicatively connected to a first branch point connected to a side closer to the chamber than the first filter of the first pipe and to which an inert gas is supplied from the other end side; a second control valve that is provided in the second pipe and controls flow of the inert gas in the second pipe; a suction pipe having one end side communicatively connected to a second branch point connected between the first filter of the first pipe and the first control valve and which is sucked from the other end side; and a control unit that supplies an ozone gas into the chamber in a state where the first control valve is opened and the second control valve is closed to treat a substrate, and then closes the first control valve and opens the second control valve to cause suction by the suction pipe to be performed when the inert gas is supplied into the chamber.

[Operation and Effect] According to the invention described in claim 1, the control unit supplies the ozone gas into the chamber in a state where the first control valve is opened and the second control valve is closed to treat the substrate, and then closes the first control valve and opens the second control valve to cause suction by the suction pipe when supplying the inert gas into the chamber. Therefore, a first filter in which the ozone gas remains and a first control valve in which particles are likely to be generated are sucked through the suction pipe. Therefore, in a first pipe, no gas flows from a second branch point to the chamber side. As a result, since the ozone gas can be prevented from being mixed into the inert gas to the chamber side, the replacement of the ozone gas can be performed in a short time, and contamination by particles can be prevented.

Further, in the present invention, it is preferable that the suction by the suction pipe is performed with a suction force with which supply of an inert gas supplied from the second pipe to the chamber is not hindered (claim 2).

When the inert gas is supplied to the chamber, the first pipe is sucked by the suction pipe at the first branch point. At this time, the suction from the suction pipe is performed with a suction force that does not hinder supply of the inert gas supplied from the second pipe to the chamber via the first branch point. Therefore, replacement of the ozone gas in the chamber with the inert gas can be reliably performed.

Further, in the present invention, it is preferable that the suction pipe includes, on the other end side, a vacuum ejector that generates a suction force caused by supplying compressed gas (claim 3).

The vacuum ejector is smaller and less expensive than a vacuum pump.

Therefore, it is possible to contribute to downsizing of the apparatus and to suppress an increase in cost.

Further, in the present invention, it is preferable that the suction pipe controls a suction force at the second branch point and includes a suction control valve operated by the control unit (claim 4).

By operating the suction control valve, the influence of suction on the second pipe at the second branch point can be reliably blocked.

Further, in the present invention, it is preferable that the second pipe includes a second filter between the first branch point and the second control valve (claim 5).

When the inert gas is supplied, it is possible to prevent adverse effects due to particles generated in the second control valve.

Further, in the present invention, it is preferable to further include: a treatment liquid chamber that accommodates a substrate and performs treatment with a treatment liquid; and a transport mechanism that transports the substrate, and that the substrate treated with an ozone gas in the chamber is transported to the treatment liquid chamber by the transport mechanism, and the substrate is processed with a treatment liquid in the treatment liquid chamber (claim 6).

The substrate that has been treated with the ozone gas in the chamber is transported to the treatment liquid chamber by the transport mechanism, and the substrate is treated with the treatment liquid. As a result, the substrate can be continuously treated with gas and liquid. Therefore, it is possible to efficiently perform the treatment of performing the treatment with the treatment liquid after performing the pretreatment with the ozone gas.

That is, the invention according to claim 7 is a substrate treatment apparatus that performs treatment of removing a film deposited to a substrate, the substrate treatment apparatus including: a chamber that accommodates a substrate and forms a sealed treatment space; a holding mechanism that holds the substrate in the chamber; an ozone gas supply source that supplies an ozone gas for treating the substrate while constantly generating the ozone gas; a supply pipe through which the ozone gas supplied from the ozone gas supply source flows; a flow pipe that communicatively connects the supply pipe and the chamber; a control valve that is provided in the flow pipe and controls flow of the ozone gas flowing through the flow pipe; an auxiliary pipe that is provided in the auxiliary pipe and communicatively connects an exhaust port for discharging gas and the supply pipe and discharges the ozone gas supplied from the ozone gas supply source to the exhaust port; an exhaust valve that adjusts a flow rate of the ozone gas flowing through the auxiliary pipe; and a control unit that closes the control valve to open the exhaust valve at the time of non-treatment in which no ozone gas is supplied to the chamber and causes the ozone gas supplied from the ozone gas supply source to be discharged to the exhaust port, and opens the control valve while adjusting a flow rate by the exhaust valve at the time of treatment in which an ozone gas is supplied to the chamber and a substrate held by the holding mechanism is processed with the ozone gas.

[Operation and Effect] According to the invention according to claim 7, since the control unit closes the control valve and opens the exhaust valve at the time of non-treatment, the ozone gas generated by the ozone gas supply source is discharged from the auxiliary pipe to the exhaust port without being supplied to the chamber. At the time of treatment, since the control unit opens the control valve while adjusting the flow rate by the exhaust valve, an ozone gas is supplied to the substrate held by the holding mechanism in the chamber from the ozone gas supply source that constantly generates an ozone gas via the flow pipe. Therefore, since there is no waiting time for the treatment with an ozone gas, the treatment time with an ozone gas can be shortened, and the throughput can be improved.

Further, in the present invention, it is preferable that a plurality of the chambers are provided, a plurality of the flow pipes are provided, each of the flow pipes branches from the supply pipe and is communicatively connected to each of the chambers, the control valve is provided in each of the plurality of flow pipes, and at the time of the treatment, at least one of the plurality of chambers is in a state of supplying an ozone gas (claim 8).

In the configuration in which the number of chambers is plural and the number of flow pipes is plural, the state in which at least one of the plurality of chambers is supplying the ozone gas is the time of treatment. Accordingly, at the time of treatment, an ozone gas having a treatment concentration is supplied from the flow pipe to at least one chamber, and treatment with an ozone gas is performed.

Further, in the present invention, the control unit adjusts the flow rate by the exhaust valve in conjunction with the flow rate by each of the control valves so that a difference between a first flow rate that is a flow rate of the ozone gas flowing through the supply pipe and a second flow rate that is a total flow rate of the ozone gas flowing through each of the flow pipes falls within a predetermined value during the treatment (claim 9).

The flow rate of the ozone gas exhausted from the auxiliary pipe is adjusted by the exhaust valve according to the flow rate of the ozone gas to each chamber by each control valve so that the difference between the flow rate of the first flow rate and the flow rate of the second flow rate is within a predetermined value. Therefore, since the reserve power corresponding to the predetermined value can be left on the supply side so that the second flow rate does not exceed the first flow rate, the ozone gas can be stably supplied to each chamber. When the flow rate by the exhaust valve is adjusted, the supply amount of the ozone gas to the plurality of chambers can be collectively adjusted.

Further, in the present invention, it is preferable that the ozone gas supply source includes a first on-off valve that allows or blocks flow of ozone gas to the supply pipe, and a first pressure adjustment mechanism that maintains a pressure of ozone gas in the supply pipe at a first pressure, and that the auxiliary pipe includes, as the exhaust valve, a second on-off valve that allows or blocks flow of ozone gas discharged to the exhaust port, and a second pressure adjustment mechanism that maintains a pressure of ozone gas in the auxiliary pipe at a second pressure smaller than the first pressure (claim 10).

The second pressure adjustment mechanism maintains the second pressure of the ozone gas in the auxiliary pipe to be smaller than the first pressure of the ozone gas in the supply pipe adjusted by the first pressure adjustment mechanism. Therefore, since the pressure difference between the ozone gas supply source and the auxiliary pipe can be secured, the flow rate of the ozone gas supplied to each chamber can be stabilized. In addition, since it is possible to prevent the ozone gas from concentrating on the auxiliary pipe, it is possible to secure the flow rate of the ozone gas necessary for the treatment in the plurality of chambers. As a result, even in a configuration including a plurality of chambers, treatment with an ozone gas can be stably performed.

Further, in the present invention, it is preferable to further include: a treatment liquid chamber that accommodates a substrate and performs treatment with a treatment liquid; and a transport mechanism that transports the substrate, and that the substrate treated with an ozone gas in the chamber is transported to the treatment liquid chamber by the transport mechanism, and the substrate is processed with a treatment liquid in the treatment liquid chamber (claim 11).

The substrate that has been treated with the ozone gas in the chamber is transported to the treatment liquid chamber by the transport mechanism, and the substrate is treated with the treatment liquid. As a result, the substrate can be continuously treated with gas and liquid. Therefore, it is possible to efficiently perform the treatment of performing the treatment with the treatment liquid after performing the pretreatment with the ozone gas.

Further, an invention according to claim 12 is a substrate treatment apparatus that performs treatment of removing a film deposited on a substrate, the substrate treatment apparatus including: a chamber including a lower lid member that supports a holding mechanism that holds the substrate at a lower portion, an upper lid member that abuts on the lower lid member from above to form a treatment space, and a raising and lowering mechanism that lowers the upper lid member with respect to the lower lid member when the substrate is processed and raises the upper lid member from the lower lid member when the substrate is not processed; an ozone gas supply source that supplies an ozone gas having a treatment concentration for treating the substrate; a first pipe that communicably connects the ozone gas supply source and the chamber; a first control valve that is provided on the first pipe and controls flow of ozone gas flowing through the first pipe; an exhaust pipe that is communicably connected to the chamber and discharges gas in the treatment space to an exhaust port outside the apparatus; a second control valve that is provided in the exhaust pipe and controls exhaust in the exhaust pipe; an exhaust mechanism including a first exhaust unit that is provided on the exhaust port side of the second control valve in the exhaust pipe and performs exhaust at a first exhaust flow rate, and a second exhaust unit that is provided on the exhaust port side of the second control valve in the exhaust pipe and performs exhaust at a second exhaust flow rate lower than the first exhaust flow rate; and a control unit that, prior to supplying an ozone gas from the ozone gas supply source to the chamber to perform ozone gas treatment, when opening the second control valve, operating the first exhaust unit, exhausting an inside of the chamber at a first exhaust flow rate to bring the upper lid member into close contact with the lower lid member, and operating the first control valve to supply an ozone gas from the ozone gas supply source to the chamber, stops the first exhaust unit and operates the second exhaust unit to exhaust the chamber at a second exhaust flow rate.

[Operation and Effect] According to the invention of claim 12, prior to supplying an ozone gas to the chamber to perform ozone gas treatment, the control unit opens the second control valve to operate the first exhaust unit, and exhausts an inside of the chamber at a first exhaust flow rate to bring the upper lid member into close contact with the lower lid member. When operating the first control valve to supply the ozone gas from the ozone gas supply source to the chamber, the control unit stops the first exhaust unit and operates the second exhaust unit to exhaust the chamber at the second exhaust flow rate. Therefore, the degree of close contact between the upper lid member and the lower lid member is increased at the first exhaust flow rate until the ozone gas is supplied, and the second exhaust flow rate lower than the first exhaust flow rate is set at the time of supplying the ozone gas. Therefore, it is possible to suppress consumption of ozone gas while preventing leakage of ozone gas.

Further, the present invention further includes: a second pipe having one end side communicatively connected to a first branch point of the first pipe and to which an inert gas is supplied from the other end side; a third control valve that controls flow of the inert gas in the second pipe; an auxiliary exhaust pipe having one end side communicatively connected to a second branch point of the exhaust pipe on the chamber side of the second control valve and the other end side communicatively connected to the exhaust port; and a fourth control valve that is provided in the auxiliary exhaust pipe and controls flow of gas in the auxiliary exhaust pipe, in which after the ozone gas treatment, the control unit operates the third control valve to supply the inert gas into the chamber, operates the first exhaust unit instead of the second exhaust unit to exhaust the chamber at a first exhaust flow rate, and replaces an ozone gas in the chamber with an inert gas, then stops the first exhaust unit and closes the second control valve, opens the fourth control valve, and then raises the upper lid member by the raising and lowering mechanism (claim 13).

After the ozone gas treatment, the control unit supplies an inert gas into the chamber, operates the first exhaust unit instead of the second exhaust unit to exhaust the chamber at the first exhaust flow rate, and replaces the ozone gas in the chamber with the inert gas. Thereafter, the controller stops the first exhaust unit, closes the second control valve, and opens the fourth control valve. As a result, only the inert gas is purged to the exhaust port in a state where the exhaust by the exhaust mechanism is stopped. Therefore, the treatment space has a positive pressure, and the close contact between the upper lid member and the lower lid member is weakened. Thereafter, since the upper lid member is raised by the raising and lowering mechanism, the upper lid member can be easily raised by the raising and lowering mechanism.

Further, in the present invention, it is preferable that the control unit raises the upper lid member, then closes the fourth control valve, opens the second control valve, and operates the second exhaust unit to exhaust the chamber at a second exhaust flow rate (claim 14).

The treatment space is exhausted at the second exhaust flow rate until the upper lid member rises and treatment of the next substrate is started. Therefore, the treatment space can be maintained in a clean state.

Further, in the present invention, it is preferable that the first exhaust unit and the second exhaust unit include a vacuum ejector that performs exhaust by supplying compressed gas (claim 15).

The vacuum ejector is smaller and less expensive than a vacuum pump. Therefore, it is possible to contribute to downsizing of the apparatus and to suppress an increase in cost.

Further, in the present invention, it is preferable to further include: a treatment liquid chamber that accommodates a substrate and performs treatment with a treatment liquid; and a transport mechanism that transports the substrate, and that the substrate treated with an ozone gas in the chamber is transported to the treatment liquid chamber by the transport mechanism, and the substrate is processed with a treatment liquid in the treatment liquid chamber (claim 16).

The substrate that has been treated with the ozone gas in the chamber is transported to the treatment liquid chamber by the transport mechanism, and the substrate is treated with the treatment liquid. As a result, the substrate can be continuously treated with gas and liquid. Therefore, it is possible to efficiently perform the treatment of performing the treatment with the treatment liquid after performing the pretreatment with the ozone gas.

### Advantageous Effects of Invention

According to the invention described in claim 1, the control unit supplies the ozone gas into the chamber in a state where the first control valve is opened and the second control valve is closed to treat the substrate, and then closes the first control valve and opens the second control valve to cause suction by the suction pipe when supplying the inert gas into the chamber. Therefore, a first filter in which the ozone gas remains and a first control valve in which particles are likely to be generated are sucked through the suction pipe. Therefore, in a first pipe, no gas flows from a second branch point to the chamber side. As a result, since the ozone gas can be prevented from being mixed into the inert gas to the chamber side, the replacement of the ozone gas can be performed in a short time, and contamination by particles can be prevented.

Further, according to the invention according to claim 7, since the control unit closes the control valve and opens the exhaust valve at the time of non-treatment, the ozone gas generated by the ozone gas supply source is discharged from the auxiliary pipe to the exhaust port without being supplied to the chamber. At the time of treatment, since the control unit opens the control valve while adjusting the flow rate by the exhaust valve, an ozone gas is supplied to the substrate held by the holding mechanism in the chamber from the ozone gas supply source that constantly generates an ozone gas via the flow pipe. Therefore, since there is no waiting time for the treatment with an ozone gas, the treatment time with an ozone gas can be shortened, and the throughput can be improved.

Further, according to the invention of claim 12, prior to supplying an ozone gas to the chamber to perform ozone gas treatment, the control unit opens the second control valve to operate the first exhaust unit, and exhausts an inside of the chamber at a first exhaust flow rate to bring the upper lid member into close contact with the lower lid member. When operating the first control valve to supply the ozone gas from the ozone gas supply source to the chamber, the control unit stops the first exhaust unit and operates the second exhaust unit to exhaust the chamber at the second exhaust flow rate. Therefore, the degree of close contact between the upper lid member and the lower lid member is increased at the first exhaust flow rate until the ozone gas is supplied, and the second exhaust flow rate lower than the first exhaust flow rate is set at the time of supplying the ozone gas. Therefore, it is possible to suppress consumption of ozone gas while preventing leakage of ozone gas.

### BRIEF DESCRIPTION OF DRAWINGS

FIG. 1 is a perspective view showing an overall configuration of a substrate treatment apparatus according to an embodiment.

FIG. 2 is a cross-sectional view taken along a line 101 -101 in FIG. 1.

FIG. 3 is a cross-sectional view taken along a line 103 -103 in FIG. 1.

FIG. 4 is a plan view schematically showing a substrate treatment apparatus.

FIG. 5 is a graph showing a change in ozone gas concentration in an ozone gas supply unit.

FIG. 6 is a diagram showing an ozone gas bake unit and a supply system and an exhaust system for gas.

FIG. 7 is a diagram for explaining non-treatment with an ozone gas.

FIG. 8 is a diagram for explaining treatment with an ozone gas.

FIG. 9 is a flowchart showing an example of an operation.

FIG. 10 is a schematic view for explaining a state in which an ozone gas is supplied.

FIG. 11 is a schematic view for explaining a state in which nitrogen gas is supplied.

FIG. 12 is a schematic view for explaining weak exhaust before treatment.

FIG. 13 is a schematic view for explaining strong exhaust in a state where an upper lid is closed.

FIG. 14 is a schematic view for explaining weak exhaust during ozone gas treatment.

FIG. 15 is a schematic view for explaining strong exhaust in replacement with nitrogen gas.

FIG. 16 is a schematic view for explaining purge in upper lid opening.

FIG. 17 is a schematic view for explaining weak exhaust after the treatment.

### DESCRIPTION OF EMBODIMENTS

Hereinafter, each embodiment of the present invention will be described.

### First Embodiment

Hereinafter, a first embodiment of the present invention will be described with reference to the drawings.

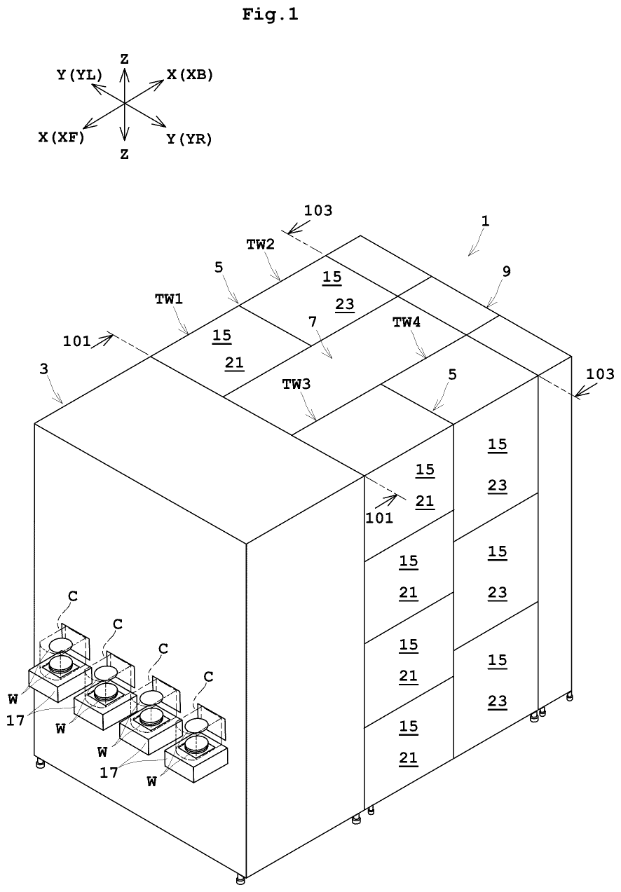

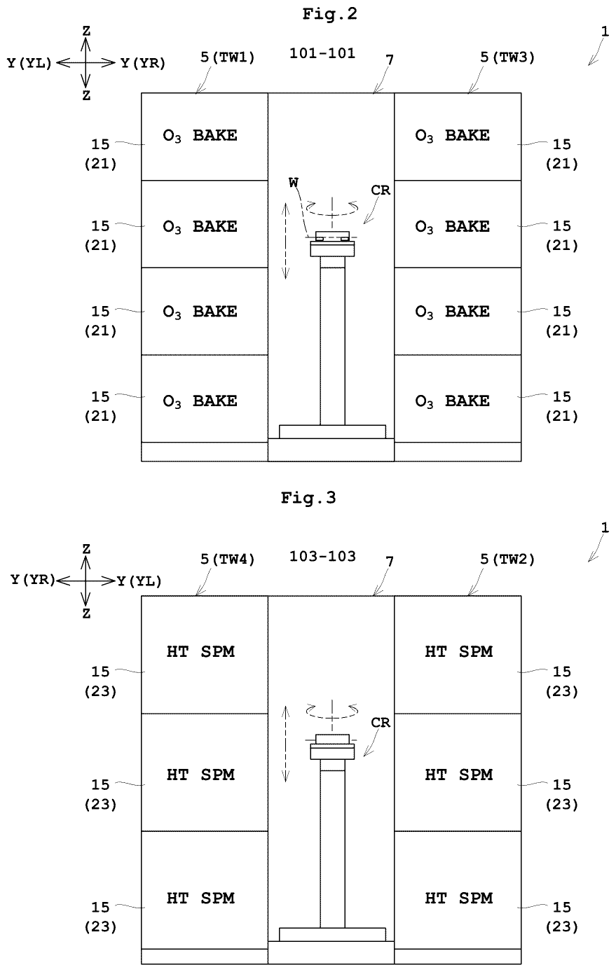

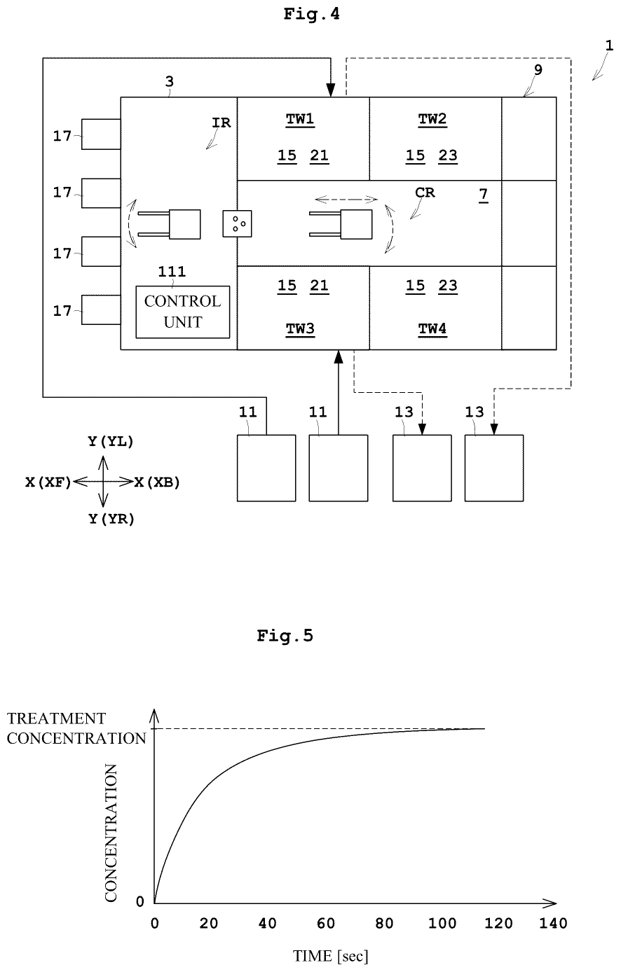

FIG. 1 is a perspective view showing an overall configuration of a substrate treatment apparatus according to an embodiment. FIG. 2 is a cross-sectional view taken along a line 101 -101 in FIG. 1. FIG. 3 is a cross-sectional view taken along a line 103 -103 in FIG. 1. FIG. 4 is a plan view schematically showing the substrate treatment apparatus.

A substrate treatment apparatus 1 according to the embodiment is, for example, an apparatus that performs removal treatment of a photoresist film on a substrate W on which a photoresist film is formed. It is particularly useful when the photoresist film is cured. Specifically, the substrate treatment apparatus 1 is suitable for performing ozone gas treatment and SPM treatment after the on-gas treatment on the substrate W in this order.

The substrate treatment apparatus 1 includes an indexer block 3, a treatment blocks 5, a transport block 7, a treatment liquid supply block 9, ozone gas supply units 11, and ozone gas decomposition units 13.

The indexer block 3 delivers the substrate W to be processed to and from the transport block 7. The transport block 7 transports the substrate W between the indexer block 3 and the treatment block 5 or between the treatment blocks 5. The treatment block 5 includes a plurality of treatment units 15. The treatment liquid supply block 9 supplies various treatment liquids used in the treatment block 5 to the treatment block 5. The ozone gas supply unit 11 supplies the ozone gas used in the treatment block 5. The ozone gas decomposition unit 13 takes in the ozone gas discharged from the treatment block 5, detoxifies the ozone gas, and discharges the ozone gas. The gas discharged from the ozone gas decomposition unit 13 is discharged to, for example, an exhaust port provided in the clean room. This exhaust port is communicably connected to, for example, an exhaust facility of a factory.

As shown in FIG. 1, in the substrate treatment apparatus 1, the indexer block 3, the treatment block 5, the transport block 7, and the treatment liquid supply block 9 are arranged in this order.

In the following description, a direction in which the indexer block 3, the treatment block 5, the transport block 7, and the treatment liquid supply block 9 are arranged is referred to as a “front-rear direction X” (horizontal direction). In particular, a direction from the treatment block 5 and the transport block 7 toward the indexer block 3 is referred to as “front XF”, and a direction opposite to the front XF direction is referred to as “rear XB”. A direction orthogonal to the front-rear direction X in the horizontal direction is referred to as a “width direction Y”. Further, when viewed from the front of the indexer block 3, one direction in the width direction Y is appropriately referred to as “right YR”, and the other direction opposite to the right YR is referred to as “left YL”. A direction which is vertical is defined as an “up-down direction Z” (height direction, vertical direction). It should be noted that the terms “lateral” and “lateral direction” are not limited to either the front-rear direction X or the width direction Y.

The indexer block 3 includes carrier placing portions 17 and an indexer robot IR. The substrate treatment apparatus 1 according to the present embodiment includes, for example, four carrier placing portions 17. Specifically, the four carrier placing portions 17 are provided so as to be arranged in a line in the width direction Y. A carrier C is placed on each carrier placing portion 17. The carrier C stores a plurality of (for example, 25 sheets) substrates W in a stacked manner, and each carrier placing portion 17 delivers and receives the carrier C to and from an overhead hoist transport (OHT: also referred to as an overhead travelling unmanned carrier) (not shown), for example. The OHT transports the carrier C using the ceiling of the clean room. Examples of the carrier C include a front opening unified pod (FOUP).

In the indexer block 3, the indexer robot IR is arranged at the rear XB of the carrier placing portion 17. The indexer robot IR delivers the substrate W to and from the carrier C, and delivers the substrate W to and from a passing unit 19. The passing unit 19 is arranged between the indexer block 3 and the transport block 7 in the front-rear direction X. Only one indexer robot IR is arranged in the indexer block 3. The indexer robot IR is attached at a fixed position so that the base does not move in the width direction Y. The indexer robot IR includes, for example, an articulated arm that can raise and lower in the up-down direction Z. The indexer robot IR is configured to be accessible to four carriers C and the passing unit 19.

The passing unit 19 includes a plurality of support pins (for example, three) on a support base. The passing unit 19 abuts and supports the substrate W in a horizontal posture. In the passing unit 19, an untreated substrate W is placed and a treated substrate W is taken out by the indexer robot IR. In the passing unit 19, the untreated substrate W is taken out by the center robot CR of the transport block 7, and the treated substrate W is placed. The passing unit 19 is configured in multiple stages in the up-down direction Z. Therefore, a plurality of substrates W are placed on the passing unit 19 at the same time.

The transport block 7 includes, for example, one center robot CR. The center robot CR is configured to be movable in the front-rear direction X and raised and lowered in the up-down direction Z. The center robot CR is configured to be turnable in a horizontal plane about the up-down direction Z. The center robot CR is configured to be able to transfer the substrate W to and from the treatment blocks 5 arranged on the right side YR and the left side YL in the width direction Y with reference to the position of the center robot CR. The center robot CR can transfer the substrate W to and from the indexer robot IR via the passing unit 19.

The treatment block 5 is arranged on the right side YR and the left side YL in the width direction Y with the transport block 7 interposed therebetween. Here, in plan view, one arranged in the up-down direction Z of the front side XF and the left side YL among the treatment blocks 5 is referred to as a tower TW1. Similarly, one arranged in the up-down direction Z of the rear side XB and the left side YL is referred to as a tower TW2. Furthermore, one arranged in the up-down direction Z of the front side XF and the right side YR is referred to as a tower TW3. In addition, one arranged in the up-down direction Z of the rear side XB and the right side YR is referred to as a tower TW4.

The towers TW1 and TW3 of the treatment block 5 are configured, for example, by stacking and arranging four treatment units 15 in the up-down direction Z. The towers TW1 and TW3 include, for example, an ozone gas bake unit 21 (in FIG. 2, it is written together with O₃ BAKE) as the treatment unit 15. The ozone gas bake unit 21 heats the substrate W at a predetermined temperature and supplies an ozone gas to treat the substrate W. Details of the structure will be described later. The ozone gas bake unit 21 cools the substrate W after finishing the treatment with the ozone gas.

The cooled substrate W is transported to the treatment units 15 of the towers TW2 and TW4 by the center robot CR.

The towers TW2 and TW4 of the treatment block 5 are configured, for example, by stacking and arranging three treatment units 15 in the up-down direction Z. The towers TW2 and TW4 include, for example, an SPM unit 23 (in FIG. 3, it is described together with HT SPM) as the treatment unit 15. The SPM unit 23 supplies the SPM heated to a predetermined temperature to the substrate W to perform treatment. This SPM is a sulfuric hydrogen peroxide mixture (SPM) which is a mixed solution of sulfuric acid and hydrogen peroxide water. The substrate W treated by the ozone gas bake unit 21 is transported to the SPM unit 23 by the center robot CR. The substrate W treated by the SPM unit 23 is transported to the passing unit 19 by the center robot CR after the SPM is removed by pure water.

The SPM unit 23 corresponds to a “treatment liquid chamber” in the present invention, and the center robot CR corresponds to a “transport mechanism” in the present invention.

As shown in FIG. 4, the substrate treatment apparatus 1 is provided with two ozone gas supply units 11 and two ozone gas decomposition units 13. The ozone gas supply unit 11 supplies ozone having a treatment concentration used for treatment in the ozone gas bake unit 21 while generating ozone. For example, when the ozone gas supply unit 11 starts the apparatus with the target concentration as the treatment concentration from a stop state in which no ozone gas is generated, the concentration of ozone gas supplied from the ozone gas supply unit changes as shown in FIG. 5, for example. FIG. 5 is a graph showing a change in ozone gas concentration in the ozone gas supply unit.

As described above, it can be seen that the ozone gas supply unit 11 has a characteristic that the concentration does not reach the treatment concentration unless nearly 2 minutes elapse after the apparatus is started. Ozone gas having a treatment concentration is supplied from one ozone gas supply unit 11 to the four ozone gas bake units 21 of the tower unit TW1 described above. In addition, an ozone gas having a treatment concentration is supplied from the other ozone gas supply unit 11 to the four ozone gas bake units 21 of the tower unit TW3.

The ozone gas decomposition unit 13 takes in gas containing an ozone gas discharged from the ozone gas bake unit 21 and detoxifies the ozone gas. The detoxified gas is discharged to, for example, an exhaust port provided in the clean room. One ozone gas decomposition unit 13 of the two ozone gas decomposition units 13, for example, processes exhaust gas from the four ozone gas bake units 21 of the tower TW1. The remaining one ozone gas decomposition unit 13 processes exhaust gas from the four ozone gas bake units 21 of the tower TW3, for example.

The ozone gas supply unit 11 corresponds to an “ozone gas supply source” in the present invention.

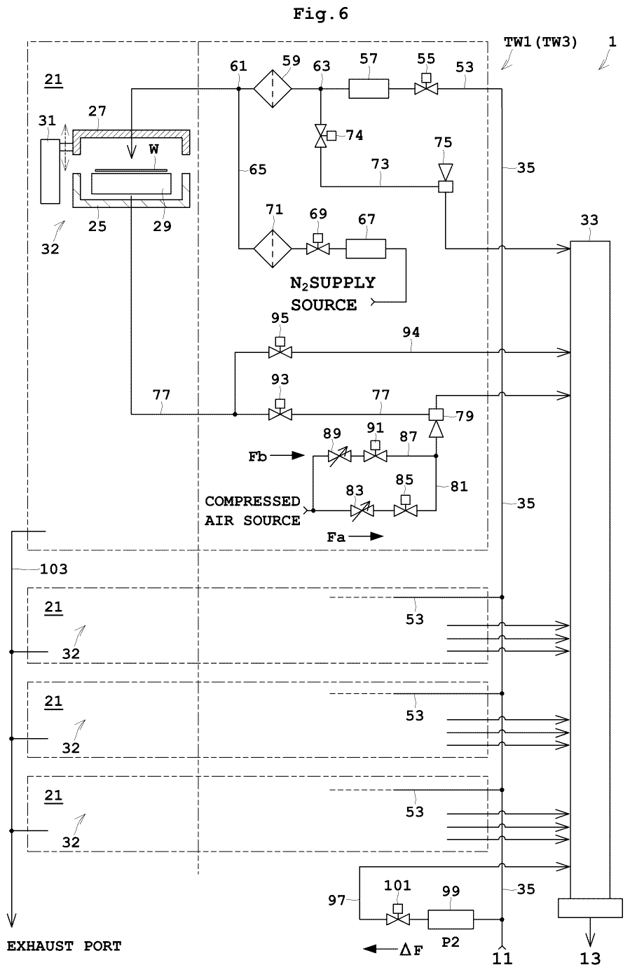

Reference is now made to FIG. 6. FIG. 6 is a diagram showing an ozone gas bake unit and a supply system and an exhaust system for gas. In the following description, the ozone gas bake unit 21 of the tower unit TW1 will be described as an example, but the ozone gas bake unit 21 of the tower unit TW3 has a similar configuration.

Each ozone gas bake unit 21 constituting the tower unit TW1 includes a chamber 32 including a lower lid 25, an upper lid 27, a heat treatment plate 29, and a raising and lowering mechanism 31. The raising and lowering mechanism 31 includes a connecting portion connected to the upper lid 27 and a motor that moves the connecting portion. The lower lid 25 is arranged on the lower side in the up-down direction Z. The lower lid 25 is a housing having an opening on the upper side. The upper lid 27 is a housing having an opening portion on the lower side. The lower lid 25 includes the heat treatment plate 29. The heat treatment plate 29 abuts and supports the substrate W. The heat treatment plate 29 heats the substrate W to a predetermined temperature. The upper lid 27 descends and comes into contact with the lower lid 25. The opening of the upper lid 27 and the opening of the lower lid 25 have substantially the same shape, the upper lid 27 and the lower lid 25 can be brought into contact with and separated from each other by the raising and lowering mechanism 31, and the upper lid 27 and the lower lid 25 form a closed space inside by joining the upper lid 27 and the lower lid 25. The closed space including the heat treatment plate 29 is a treatment space in which the substrate W is treated. The upper lid 27 is lifted and lowered with respect to the lower lid 25 by the raising and lowering mechanism 31. The raising and lowering mechanism 31 lowers the upper lid 27 to the lower lid 25 at the time of treatment in which the substrate W is processed. On the other hand, the raising and lowering mechanism 31 transfers the substrate W to and from the treatment space, and raises the upper lid 27 above the lower lid 25 at the time of non-treatment in which the treatment is not performed.

The tower unit TW1 includes one exhaust main pipe 33. The exhaust main pipe 33 is arranged from the lowermost layer to the uppermost layer in the tower unit TW1. A lower portion of the exhaust main pipe 33 is connected to communicate with the ozone gas decomposition unit 13. The tower unit TW1 includes one supply pipe 35. The supply pipe 35 is also arranged from the lowermost layer to the uppermost layer in the tower unit TW1. One end side of the supply pipe 35 is connected to communicate with the ozone gas supply unit 11. Ozone gas having a treatment concentration is supplied from the ozone gas supply unit 11 to the supply pipe 35.

The heat treatment plate 29 corresponds to a “holding mechanism” in the present invention.

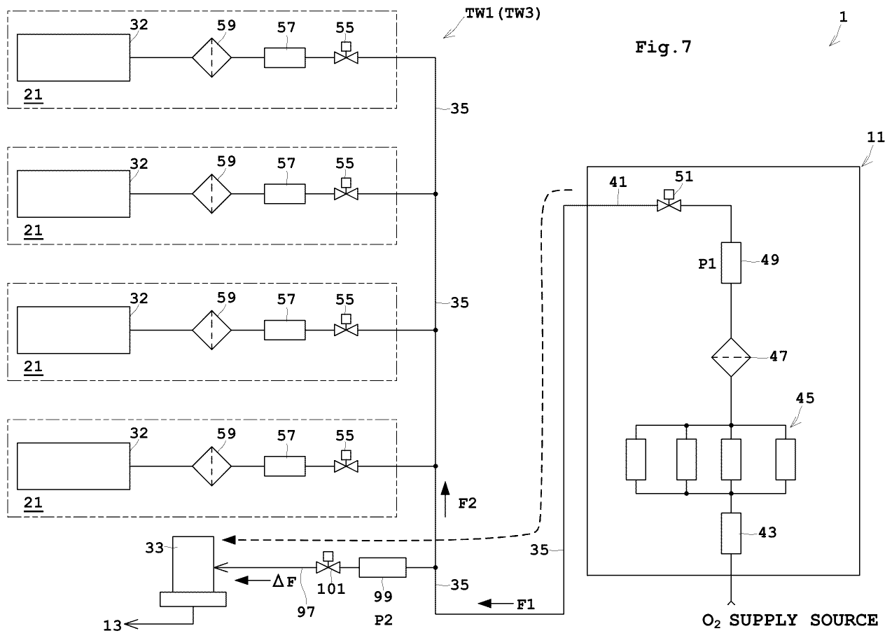

Reference is now made to FIG. 7. Note that FIG. 7 is a diagram for description at the time of non-treatment with an ozone gas.

The ozone gas supply unit 11 includes a generation pipe 41, a mass flow controller 43, an ozone gas generator 45, a filter 47, an automatic pressure regulator 49, and a control valve 51.

One end side of the generation pipe 41 is communicably connected to, for example, an oxygen supply source (not shown) which is one of utilities provided in the clean room. The other end side of the generation pipe 41 is communicably connected to the supply pipe 35. The mass flow controller 43, the ozone gas generator 45, the filter 47, the automatic pressure regulator 49, and the control valve 51 are attached to the generation pipe 41 in this order from the oxygen supply source side toward the supply pipe 35 side.

The mass flow controller 43 controls a flow rate of oxygen supplied to the generation pipe 41 to a predetermined flow rate. The ozone gas generator 45 is configured by, for example, arranging four ozone gas generation modules in parallel. Each ozone gas generation module generates an ozone gas from oxygen. Particles and the like of the ozone gas generated by the ozone gas generator 45 are removed by the filter 47. The ozone gas that has passed through the filter 47 is adjusted to a predetermined first pressure P1 (for example, 200 kPa) by the automatic pressure regulator 49. The control valve 51 controls the flow of the ozone gas adjusted to the first pressure P1 to the supply pipe 35.

The ozone gas supply unit 11 described above can supply an ozone gas at a flow rate of, for example, 100 liters/minute at the maximum. In the above-described automatic pressure regulator 49, since the adjusted pressure is set to the first pressure P1, the pressure in the most downstream portion of the generation pipe 41 (communication connection portion with the supply pipe 35) is adjusted to be the first pressure P1 (in the embodiment, for example, 200 kPa). The flow rate of the ozone gas in the supply pipe 35 is a first flow rate F1 (for example, 100 liters/minute) at the maximum according to the performance of the ozone gas supply unit 11.

Returning to FIG. 6. The supply pipe 35 communicatively connected to the other end side of the generation pipe 41 of the ozone gas supply unit 11 is branched into each ozone gas bake unit 21. The ozone gas bake unit 21 is communicably connected to a flow pipe 53 provided to branch from the supply pipe 35 to each chamber 32. Specifically, one end side of the flow pipe 53 is communicatively connected to the supply pipe 35, and the other end side is communicatively connected to each chamber 32. Specifically, the other end side of the flow pipe 53 is attached to the upper lid 25 and is connected to communicate with the treatment space formed in the chamber 32.

The flow pipe 53 is provided with a control valve 55, a mass flow controller 57, and a filter 59 in this order from the supply pipe 35 toward the chamber 32. The control valve 55 controls the flow of the ozone gas from the supply pipe 35 to the chamber 32. The mass flow controller 57 adjusts the flow rate of the ozone gas supplied to the chamber 32 through the flow pipe 53. The filter 59 removes particles and the like contained in the ozone gas flowing through the flow pipe 53.

For example, in the mass flow controller 57, the flow rate of the ozone gas is set to 20 liters/minute at the maximum, and the treatment flow rate is set to 10 liters/minute.

The flow pipe 53 is provided with a first branch point 61 and a second branch point 63. The first branch point 61 is provided between the chamber 32 and the filter 59 in the flow pipe 53. In other words, the first branch point 61 is provided on the chamber 32 side of the filter 59 in the flow pipe 53. The second branch point 63 is provided between the filter 59 and the mass flow controller 57 and the control valve 55 in the flow pipe 53.

One end side of the inert gas supply pipe 65 is communicably connected to the first branch point 61. The other end side of the inert gas supply pipe 65 is communicably connected to, for example, a nitrogen gas supply source which is one of utilities of a clean room. A mass flow controller 67, a control valve 69, and a filter 71 are attached to the inert gas supply pipe 65 in this order from the nitrogen gas supply source side toward the first branch point 61. The mass flow controller 67 adjusts the flow rate of the nitrogen gas supplied to the inert gas supply pipe 65. The control valve 69 controls the flow of the nitrogen gas in the inert gas supply pipe 65. The filter 71 removes particles and the like contained in the nitrogen gas flowing through the inert gas supply pipe 65. The inert gas supply pipe 65 preferably includes, for example, a check valve between the control valve 69 and the mass flow controller 67 so that an ozone gas does not flow from the flow pipe 53.

The flow pipe 53 corresponds to a “first pipe” in the present invention, the control valve 55 corresponds to a “first control valve” in the present invention, and the filter 59 corresponds to a “first filter” in the present invention. The inert gas supply pipe 65 corresponds to a “second pipe” in the present invention, the control valve 69 corresponds to a “second control valve” in the present invention, and the filter 71 corresponds to a “second filter” in the present invention.

One end side of a suction pipe 73 is communicably connected to the second branch point 63. The other end side of the suction pipe 73 is connected to communicate with a suction port of a vacuum ejector 75. A discharge port of a vacuum ejector 75 is connected to communicate with the exhaust main pipe 33. In the vacuum ejector 75, when compressed air is supplied to the supply port, a flow of gas from the suction port toward the discharge port is formed. The suction pipe 73 includes a control valve 74 that controls the flow of the sucked gas.

The control valve 74 corresponds to a “suction control valve” in the present invention.

The suction from the suction pipe 73 is performed, for example, as follows.

After the ozone gas is supplied from the flow pipe 53 to the chamber 32, a process of replacing the ozone gas with nitrogen gas is performed. At that time, nitrogen gas is supplied from the inert gas supply pipe 65 to the first branch point 61. At this time, suction by the suction pipe 73 is performed. As a result, the ozone gas remaining in the filter 59 and the mass flow controller 57 can be prevented from being drawn into the chamber 32 by the flow of the nitrogen gas. Therefore, the time required for replacing the ozone gas with the nitrogen gas can be shortened. In addition, it is possible to prevent particles that may be generated in the mass flow controller 57 and the control valve 55 including a mechanical operation from being drawn into the flow of the nitrogen gas and flowing into the chamber 32.

The vacuum ejector 75 is smaller and less expensive than a vacuum pump or the like. Therefore, it is possible to contribute to miniaturization of the substrate treatment apparatus 1 and to suppress an increase in cost.

One end side of an exhaust pipe 77 is communicably connected to the chamber 32. A suction port of a vacuum ejector 79 is communicatively connected to the other end side of the exhaust pipe 77. A discharge port of the vacuum ejector 79 is connected to communicate with the exhaust main pipe 33. One end side of a first supply pipe 81 is communicatively connected to a supply port for supplying compressed air to the vacuum ejector 79 to form an exhaust flow from the suction port toward the discharge port of the vacuum ejector 79. For example, a compressed air source which is one of utilities of a clean room is communicably connected to the other end side of the first supply pipe 81.

The first drive pipe 81 is provided with a flow rate adjusting valve 83 and an on-off valve 85 in this order from the compressed air source toward the vacuum ejector 79. The flow rate adjusting valve 83 adjusts the flow rate of the compressed air so that the compressed air flows through the first drive pipe 81 at a first flow rate Fa. The on-off valve 85 controls the flow of the compressed air set to the first flow rate Fa in the first drive pipe 81. Both ends of the second drive pipe 87 are communicatively connected to a portion of the first drive pipe 81 upstream of the flow rate adjusting valve 83 and a portion of the first drive pipe 81 between the on-off valve 85 and the vacuum ejector 79. The second drive pipe 87 is provided with a flow rate adjusting valve 89 and an on-off valve 91 in this order from the compressed air source side toward the vacuum ejector 79 side. The flow rate adjusting valve 89 adjusts the flow rate of the compressed air so that the compressed air flows through the second drive pipe 87 at a second flow rate Fb. The on-off valve 91 controls the flow of the compressed air set to the second flow rate Fb in the second drive pipe 87. The flow rate adjusting valves 83 and 89 are set such that the second flow rate Fb is smaller than the first flow rate Fa.

The exhaust pipe 77 includes an on-off valve 93. In the exhaust pipe 77, one end side of a purge pipe 94 is communicably connected between the on-off valve 93 and the chamber 32. The other end side of the purge pipe 94 is connected to communicate with the exhaust main pipe 33. The purge pipe 94 includes an on-off valve 95. The on-off valve 95 controls the flow of gas in the purge pipe 94.

The exhaust by the exhaust pipe 77 described above is performed as follows.

When only the on-off valves 93 and 85 are opened among the on-off valves 85, 89, 93, and 95, the vacuum ejector 79 is operated by the first flow rate Fa. As a result, the gas in the chamber 32 is strongly sucked and strongly exhausted through the exhaust pipe 77. When only the on-off valves 91 and 93 are opened, the vacuum ejector 79 is operated by the second flow rate Fb (<first flow rate Fa). As a result, the gas in the chamber 32 is weakly sucked out and weakly exhausted through the exhaust pipe 77. When the nitrogen gas is supplied from the inert gas supply pipe 65 to the chamber 32 and only the on-off valve 95 is opened, the gas in the chamber 32 is pushed out only by the nitrogen gas through the exhaust pipe 77 and the purge pipe 94.

The supply pipe 35 includes an auxiliary pipe 97. One end side of the auxiliary pipe 97 is communicably connected to the supply pipe 35. The other end side of the auxiliary pipe 97 is communicably connected to the exhaust main pipe 33.

The auxiliary pipe 97 includes an automatic pressure regulator 99 and a control valve 101 from the supply pipe 35 toward the exhaust main pipe 33. In the automatic pressure regulator 99, the pressure of the ozone gas in the auxiliary pipe 97 branched from the supply pipe 35 is adjusted to a predetermined second pressure P2 (for example, 100 kPa). Here, the flow rate of the ozone gas in the supply pipe 35 is the first flow rate F1, and the ozone gas flowing to each chamber 32 side of the auxiliary pipe 97 in the supply pipe 35 is set to the second flow rate F2. In this case, when the flow rate of the difference between the first flow rate F1 and the second flow rate F2 is AF, the flow rate AF of the difference flows through the auxiliary pipe 97.

Each of the ozone gas bake units 21 includes an external exhaust pipe 103 that is outside the chamber 32 and discharges gas in each of the ozone gas bake units 21. The external exhaust pipe 103 exhausts gas around the chamber 32 and the above-described various pipes and valves to, for example, an exhaust port provided in the clean room.

As shown in FIG. 4, the substrate treatment apparatus 1 includes a controller 111. The control unit 111 includes a CPU and a memory. When the operator operates a control console (not shown), the control unit 111 integrally controls the operation of each unit on the basis of the operation. Specifically, the control unit 111 performs transport control of the indexer robot IR in the indexer block 3, transport control of the center robot CR in the transport block 7, treatment control of each treatment unit 15 in the treatment block 5, delivery control of various treatment liquids in the treatment liquid supply block 9, and operation control of the ozone gas supply unit 11 and the ozone gas decomposition unit 13.

Regarding the flow rate of the ozone gas, the control unit 111 operates each unit as follows, for example. It is assumed that the ozone gas supply unit 11 has already operated and is in a state of being able to supply an ozone gas having a treatment concentration, and the control valve 51 is opened. The control unit 111 described above adjusts the flow rate of the ozone gas by the mass flow controller 99 and the control valve 101 in conjunction with the flow rate by each mass flow controller 57 and the on-off valve 55 such that a difference ΔF of the flow rate described below falls within a predetermined value.

As shown in FIG. 7, at the time of non-treatment in which treatment with an ozone gas is not performed in the chamber 32, each control valve 55 is closed and the control valve 101 is opened. As a result, an ozone gas is not supplied from the supply pipe 35 to each chamber 32. The ozone gas supplied from the ozone gas supply unit 11 to the supply pipe 35 is discharged to the exhaust main pipe 33 via the auxiliary pipe 97. In this state, the pressure of ozone gas in the generation pipe 41 of the ozone gas supply unit 11 is the first pressure P1 (=200 kPa), and the pressure of ozone gas in the auxiliary pipe 97 is the second pressure P2 (=100 kPa). Regarding the flow rate, for example, the first flow rate F1 in the generation pipe 41 is 100 liters/minute, and the second flow rate F2 in the supply pipe 35 is 0 liters/minute. Therefore, a flow rate difference AF, which is a difference between the first flow rate F1 and the second flow rate F2, is 100 liters/minute.

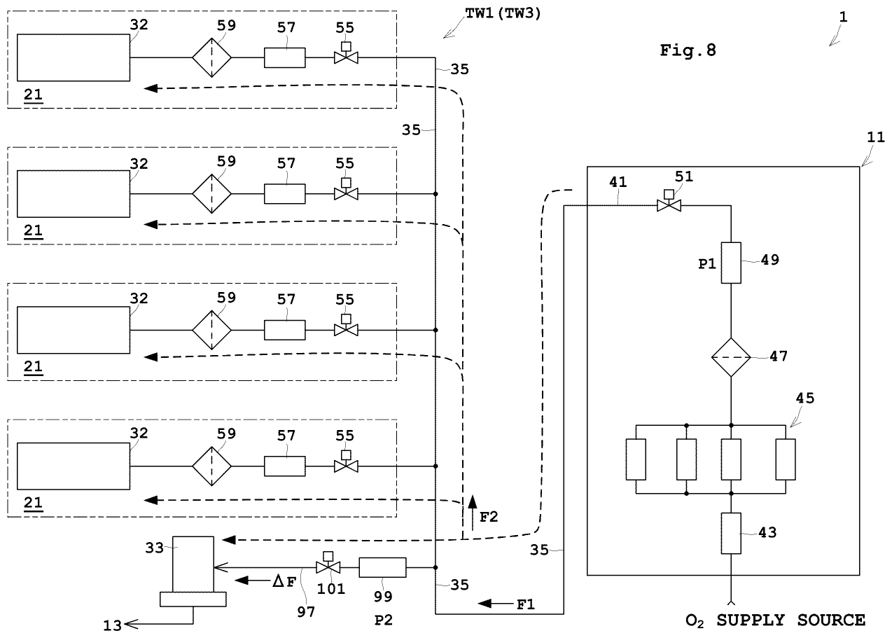

Reference is now made to FIG. 8. FIG. 8 is a diagram for explaining the treatment with an ozone gas.

At the time of treatment with an ozone gas in the chamber 32, specifically, at the time of treatment in which an ozone gas is supplied to at least one chamber 32 among the four chambers 32 and treatment with an ozone gas is performed in the chamber 32, the control valve 55 of the chamber 32 to perform treatment is opened. At this time, although the control valve 101 is opened, the flow rate is adjusted.

For example, when treatment with an ozone gas is performed in all the four chambers 32, an ozone gas is supplied at a flow rate of 20 liters/minute at the maximum according to the required amount of treatment in each chamber 32. Therefore, the second flow rate F2 is 80 liters/minute at the maximum. Since the first flow rate Fl is 100 liters/minute, the flow rate difference ΔF is 20 liters/minute at minimum. In this manner, the mass flow controller 99 and the control valve 101 are controlled such that the difference ΔF between the flow rates falls within a predetermined value. Therefore, since the reserve power corresponding to the predetermined value can be left on the ozone gas supply unit 11 side so that the second flow rate F2 does not exceed the first flow rate F1, the ozone gas can be stably supplied to each chamber 32. Conversely, the second flow rate F2 can be adjusted by adjusting the flow rate difference ΔF by the mass flow controller 99 and the control valve 101. As a result, the flow rate of the ozone gas can be changed collectively for all the four chambers 32. As a result, the control of the flow rate can be simplified as compared with the case of operating the mass flow controller 57 in each chamber 32.

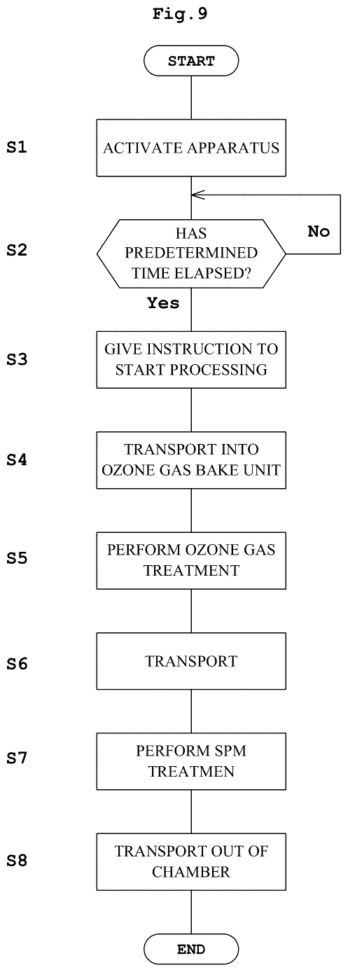

Next, treatment in the substrate treatment apparatus 1 described above will be described with reference to FIG. 9. FIG. 9 is a flowchart showing an example of the operation. In the following description, only parts related to the ozone gas treatment and the SPM treatment will be described in detail, and other operations will be simplified or omitted. In order to facilitate understanding of the invention, only the flow of one substrate W will be described.

### Step S1

The operator activates the substrate treatment apparatus 1. In conjunction with this, the ozone gas supply unit 11 and the ozone gas decomposition unit 13 are also activated. Thus, under the control of the control unit 111, the ozone gas supply unit 11 starts generation of an ozone gas to be a treatment concentration. As shown in FIG. 5, it takes about 2 minutes to generate an ozone gas having a treatment concentration.

### Step S2

The control unit 111 monitors whether or not a predetermined time until an ozone gas having a treatment concentration is generated by the ozone gas supply unit 11 has elapsed, and proceeds to the next step S3 at the time point when the predetermined time has elapsed. Even before the concentration of the ozone gas reaches the treatment concentration, all the generated ozone gas is exhausted through the exhaust main pipe 33 via the auxiliary pipe 97 as in the non-treatment with the ozone gas shown in FIG. 7.

### Step S3

The operator gives instruction to start the process from a control console (not shown).

### Step S4

The substrate W to be processed accommodated in the carrier C is transported to the passing unit 19 via the indexer block 3, and is transported into the ozone gas bake unit 21 by the center robot CR. Note that before the process of transporting the substrate W into the chamber 32 in the next step S5, the control unit 111 operates the control valve 69 and the mass flow controller 67 to supply the nitrogen gas to the chamber 32. Furthermore, the control unit 111 operates the vacuum ejector 79 by the flow rate adjusting valve 89 and the on-off valve 91. As a result, the inside of the chamber 32 is weakly exhausted, and the treatment space is kept clean with the inert gas.

### Step S5

When the substrate W is accommodated in the chamber 32, the control unit 111 moves the upper lid 27 to the lower lid 25 by the raising and lowering mechanism 31. As a result, the chamber 32 is sealed. At this time, the control unit 111 operates the flow rate adjusting valve 89 and the on-off valve 91 to stop the operation of the vacuum ejector 79 by the second drive pipe 81. Furthermore, the control unit 111 operates the vacuum ejector 79 by the flow rate adjusting valve 83 and the on-off valve 85. The flow rate of the suction port of the vacuum ejector 79 is larger than the flow rate of the nitrogen gas supplied from the inert gas supply pipe 65. As a result, since the inside of the chamber 32 is strongly exhausted, the treatment space has a negative pressure. Therefore, the upper lid 27 is strongly brought into close contact with the lower lid 25, and the chamber 32 is completely sealed with respect to the periphery.

Thereafter, the controller 111 waits until the temperature of the substrate W placed on the heat treatment plate 29 rises to a predetermined temperature (for example, 100 to 300 °C). When the temperature of the substrate W reaches a predetermined temperature, the control unit 111 starts treatment with an ozone gas.

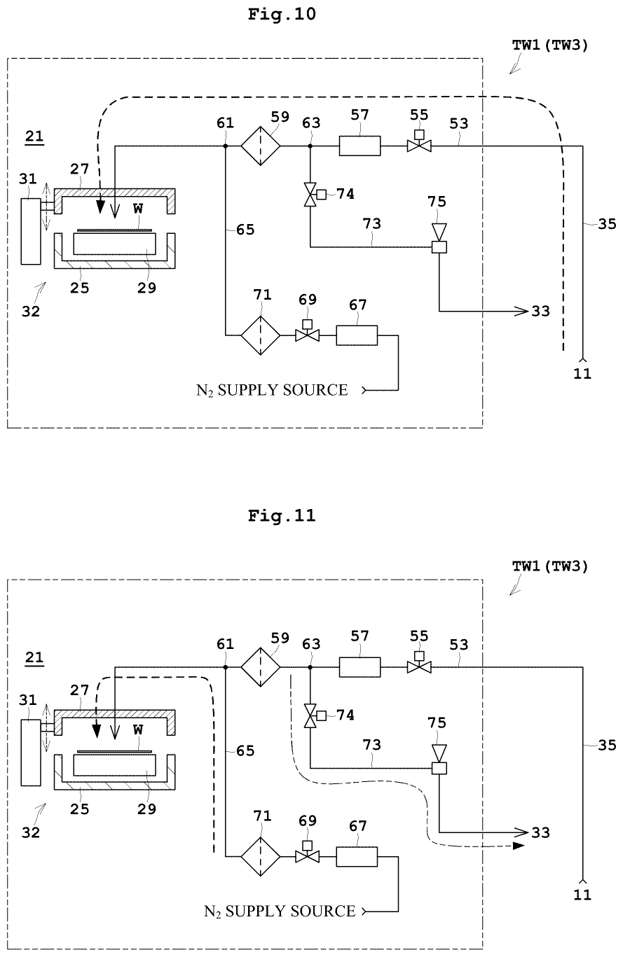

Specifically, the control unit 111 operates the mass flow controller 57 and the control valve 55 so that an ozone gas having a treatment concentration is supplied to the chamber 32 at a required flow rate. As a result, an ozone gas having a treatment concentration is supplied to the treatment space where the substrate W is placed. A state in which the ozone gas is supplied is as indicated by an arrowed broken line in FIG. 10.

At this time, the controller 111 operates the flow rate adjusting valve 83 and the on-off valve 85 to stop the strong exhaust. Furthermore, the control unit 111 operates the flow rate adjusting valve 89 and the on-off valve 91 to switch to weak exhaust. As a result, since the ozone gas having the treatment concentration stays in the treatment space, the treatment with the ozone gas can be sufficiently performed. When a predetermined ozone gas treatment time has elapsed, the control unit 111 operates the mass flow controller 57 and the control valve 55 to stop the supply of an ozone gas to the chamber 32.

Next, the control unit 111 replaces the ozone gas in the chamber 32 with nitrogen gas. Specifically, the control unit 111 operates the control valve 69 and the mass flow controller 67 to supply the nitrogen gas from the inert gas supply pipe 65 in FIG. 6 to the chamber 32. A state in which the nitrogen gas is supplied is as indicated by an arrowed broken line in FIG. 11.

In addition, the control unit 111 operates the vacuum ejector 75, opens the control valve 74, and causes the suction pipe 73 to suck the second branch point 63. A state in which the second branch point 63 is sucked is as indicated by a two-dot chain line with arrows in FIG. 11. Furthermore, the control unit 111 operates the flow rate adjusting valve 89 and the on-off valve 91 to stop the weak exhaust. At the same time, the control unit 111 operates the flow rate adjusting valve 83 and the on-off valve 85 to perform strong exhaust. Since the inside of the chamber 32 is strongly exhausted, the ozone gas in the treatment space is efficiently replaced with the nitrogen gas. Therefore, the time required for replacement can be shortened. At this time, as indicated by an arrowed two-dot chain line in FIG. 11, since the suction of the second branch point 63 is simultaneously performed, it is possible to prevent the ozone remaining in the filter 59 from being mixed into the treatment space. Therefore, the replacement efficiency with nitrogen gas can be improved. Furthermore, since the second branch point 63 is provided between the filter 59 and the mass flowmeter 57 and the control valve 55, it is possible to prevent particles that are likely to be generated in the mass flowmeter 57 and the control valve 55 from flowing into the treatment space. Therefore, the substrate W can be cleaned.

The suction of the suction pipe 73 is performed with a suction force that does not hinder the supply of the nitrogen gas supplied to the chamber 32 via the first branch point 61. Therefore, the ozone gas in the chamber 32 can be reliably replaced with the nitrogen gas.

When the replacement with the nitrogen gas is completed, the control unit 111 operates the flow rate adjusting valve 83 and the on-off valve 85 to stop the strong exhaust. The controller 111 opens the on-off valve 95. As a result, the inert gas is discharged only by the supply pressure through the purge pipe 94. At this time, since the chamber 32 has a positive pressure, the raising operation of the upper lid 25 by the raising and lowering mechanism 31 is smoothly performed. After the upper lid 25 is raised, the control unit 111 closes the on-off valve 95 and operates the flow rate adjusting valve 89 and the on-off valve 91 to perform weak exhaust. This keeps the treatment space clean with the inert gas. The controller 111 moves the substrate W to a cooling unit (not shown) to return the substrate W to room temperature.

### Step S6

The controller 111 operates the center robot CR to take out the substrate W from the ozone gas bake unit 21 and transport the substrate W to the SPM unit 23.

### Step S7

The control unit 111 supplies the SPM to the surface of the substrate W while heating the substrate W. As a result, the photoresist film on the surface of the substrate W is removed by the SPM. At this time, since the surface of the photoresist film is ashed to some extent by pretreatment with an ozone gas, the photoresist film can be easily removed by a small amount of SPM even if the surface of the photoresist film is cured. After the treatment of the substrate W by the SPM is completed, the control unit 111 performs a cleaning treatment and a drying treatment with pure water.

### Step S8

The control unit 111 operates the center robot CR to transport the substrate W to the passing unit 19, and operates the indexer robot IR to carry the substrate W out to return it to the carrier C. By such a series of operations, removal treatment of the photoresist film on the substrate W is performed.

According to the present embodiment, the control unit 111 opens the control valve 55, supplies an ozone gas into the chamber 32 in a state where the control valve 69 is closed to treat the substrate W, then closes the control valve 55, and opens the control valve 69 to cause the suction pipe 73 to perform suction when supplying nitrogen gas into the chamber 32. Therefore, the filter 59 in which the ozone gas remains, the mass flow controller 57, and the control valve 55 are sucked via the suction pipe 73. Therefore, in the flow pipe 53, gas does not flow from the second branch point 63 toward the chamber 32. As a result, since the ozone gas can be prevented from being mixed into the nitrogen gas on the chamber 32 side, the replacement of the ozone gas can be performed in a short time, and contamination by particles can be prevented.

The present invention is not limited to the above embodiment, and can be modified as follows.
(1) In the above-described embodiment, the substrate treatment apparatus 1 including the four chambers 32 and the four flow pipes 53 has been described as an example. However, the present invention does not necessarily include the plurality of chambers 32 and the plurality of flow pipes 53. That is, the present invention can be applied to the substrate treatment apparatus 1 including one chamber 32 and one flow pipe 53.
(2) In the above-described embodiment, nitrogen gas is employed as the inert gas. However, the present invention is not limited to nitrogen gas as the inert gas, and for example, argon gas can also be applied.
(3) In the above-described embodiment, a configuration in which the suction pipe 73 is sucked by the vacuum ejector 75 is adopted. However, the present invention is not limited to such a configuration. For example, the suction pipe 73 may be sucked by a suction unit such as a vacuum pump.
(4) In the above-described embodiment, the substrate treatment apparatus 1 includes the ozone gas decomposition unit 13, but the present invention does not require the ozone gas decomposition unit 13.
(5) In the above-described embodiment, the substrate treatment apparatus 1 includes the SPM unit 23, but the present invention does not require the SPM unit 23.

For example, the substrate W processed by the ozone gas bake unit 21 may be processed by the SPM unit 23 included in another apparatus.
(6) In the above-described embodiment, the substrate treatment apparatus 1 includes the indexer block 3, the transport block 7, the carrier placing portion 17, the passing unit 19, and the like, and is configured to continuously transport a plurality of substrates W to perform treatment efficiently, but the present invention is not limited to such a configuration. That is, the present invention can also be applied to a substrate treatment apparatus that does not include a transfer system or the like and includes a configuration for performing treatment with an ozone gas having a treatment concentration.

### Second Embodiment

Next, a second embodiment of the present invention will be described with reference to the drawings.

Configurations common to the first embodiment described above are denoted by the same reference numerals, and a detailed description thereof will be omitted.

As shown in FIG. 5, the ozone gas supply unit 11 has a characteristic that a target predetermined concentration is not reached unless nearly 2 minutes elapse after the apparatus is started. Ozone gas having a predetermined treatment concentration is supplied from the ozone gas supply unit 11 to the supply pipe 35 described above.

Correspondence relationship with each component in claims 7 to 11 of the present invention is as follows.

The SPM unit 23 corresponds to a “treatment liquid chamber”, and the center robot CR corresponds to a “transport mechanism”. The ozone gas supply unit 11 corresponds to an “ozone gas supply source”. The heat treatment plate 29 corresponds to a “holding mechanism”. The automatic pressure regulator 49 corresponds to a “first pressure adjustment mechanism”, the control valve 55 corresponds to a “control valve”, and the control valve 51 corresponds to a “first on-off valve”. The control valve 101 corresponds to an “exhaust valve”, the automatic pressure regulator 99 corresponds to a “second pressure adjustment mechanism”, and the control valve 101 corresponds to a “second on-off valve”.

Next, treatment in the second embodiment will be described with reference to FIG. 9.

### Step S1

The operator activates the substrate treatment apparatus 1. In conjunction with this, the ozone gas supply unit 11 and the ozone gas decomposition unit 13 are also activated. Thus, under the control of the control unit 111, the ozone gas supply unit 11 starts generation of an ozone gas to be a treatment concentration. As shown in FIG. 5, it takes about 2 minutes to generate an ozone gas having a treatment concentration.

### Step S2

The control unit 111 monitors whether or not a predetermined time until an ozone gas having a treatment concentration is generated by the ozone gas supply unit 11 has elapsed, and proceeds to the next step S3 at the time point when the predetermined time has elapsed. Even before the concentration of the ozone gas reaches the treatment concentration, all the generated ozone gas is exhausted through the exhaust main pipe 33 via the auxiliary pipe 97 as in the non-treatment with the ozone gas shown in FIG. 7.

### Step S3

The operator gives instruction to start the process from a control console (not shown).

### Step S4

The substrate W to be processed accommodated in the carrier C is transported to the passing unit 19 via the indexer block 3, and is transported into the ozone gas bake unit 21 by the center robot CR. Note that before the process of transporting the substrate W into the chamber 32 in the next step S5, the control unit 111 operates the control valve 69 and the mass flow controller 67 to supply the nitrogen gas to the chamber 32. Furthermore, the control unit 111 operates the vacuum ejector 79 by the flow rate adjusting valve 89 and the on-off valve 91. As a result, the inside of the chamber 32 is weakly exhausted, and the treatment space is kept clean with the inert gas.

### Step S5

When the substrate W is accommodated in the chamber 32, the control unit 111 moves the upper lid 27 to the lower lid 25 by the raising and lowering mechanism 31. As a result, the chamber 32 is sealed. At this time, the control unit 111 operates the flow rate adjusting valve 89 and the on-off valve 91 to stop the operation of the vacuum ejector 79 by the second drive pipe 81. Furthermore, the control unit 111 operates the vacuum ejector 79 by the flow rate adjusting valve 83 and the on-off valve 85. The flow rate of the suction port of the vacuum ejector 79 is larger than the flow rate of the nitrogen gas supplied from the inert gas supply pipe 65. As a result, since the inside of the chamber 32 is strongly exhausted, the treatment space has a negative pressure. Therefore, the upper lid 27 is strongly brought into close contact with the lower lid 25, and the chamber 32 is completely sealed with respect to the periphery.

Thereafter, the controller 111 waits until the temperature of the substrate W placed on the heat treatment plate 29 rises to a predetermined temperature (for example, 100 to 300 °C). When the temperature of the substrate W reaches a predetermined temperature, the control unit 111 starts treatment with an ozone gas.

Specifically, the control unit 111 operates the mass flow controller 57 and the control valve 55 so that an ozone gas having a treatment concentration is supplied to the chamber 32 at a required flow rate. As a result, an ozone gas having a treatment concentration is supplied to the treatment space where the substrate W is placed. At this time, the controller 111 operates the flow rate adjusting valve 83 and the on-off valve 85 to stop the strong exhaust. Furthermore, the control unit 111 operates the flow rate adjusting valve 89 and the on-off valve 91 to switch to weak exhaust. As a result, since the ozone gas having the treatment concentration stays in the treatment space, the treatment with the ozone gas can be sufficiently performed. When a predetermined ozone gas treatment time has elapsed, the control unit 111 operates the mass flow controller 57 and the control valve 55 to stop the supply of an ozone gas to the chamber 32.

Next, the control unit 111 replaces the ozone gas in the chamber 32 with nitrogen gas. Specifically, the control unit 111 operates the control valve 69 and the mass flow controller 67 to supply the nitrogen gas from the inert gas supply pipe 65 in FIG. 6 to the chamber 32. In addition, the control unit 111 operates the vacuum ejector 75, opens the control valve 74, and causes the suction pipe 73 to suck the second branch point 63. Furthermore, the control unit 111 operates the flow rate adjusting valve 89 and the on-off valve 91 to stop the weak exhaust. At the same time, the control unit 111 operates the flow rate adjusting valve 83 and the on-off valve 85 to perform strong exhaust. Since the inside of the chamber 32 is strongly exhausted, the ozone gas in the treatment space is efficiently replaced with the nitrogen gas. Therefore, the time required for replacement can be shortened. At this time, since the suction of the second branch point 63 is simultaneously performed, it is possible to prevent the ozone remaining in the filter 59 from being mixed into the treatment space. Therefore, the replacement efficiency with nitrogen gas can be improved. Furthermore, since the second branch point 63 is provided between the filter 59 and the mass flowmeter 57 and the control valve 55, it is possible to prevent particles that are likely to be generated in the mass flowmeter 57 and the control valve 55 from flowing into the treatment space. Therefore, the substrate W can be cleaned.

When the replacement with the nitrogen gas is completed, the control unit 111 operates the flow rate adjusting valve 83 and the on-off valve 85 to stop the strong exhaust. The controller 111 opens the on-off valve 95. As a result, the inert gas is discharged only by the supply pressure through the purge pipe 94. At this time, since the chamber 32 has a positive pressure, the raising operation of the upper lid 25 by the raising and lowering mechanism 31 is smoothly performed. After the upper lid 25 is raised, the control unit 111 closes the on-off valve 95 and operates the flow rate adjusting valve 89 and the on-off valve 91 to perform weak exhaust. This keeps the treatment space clean with the inert gas. The controller 111 moves the substrate W to a cooling unit (not shown) to return the substrate W to room temperature.

### Step S6

The controller 111 operates the center robot CR to take out the substrate W from the ozone gas bake unit 21 and transport the substrate W to the SPM unit 23.

### Step S7

The control unit 111 supplies the SPM to the surface of the substrate W while heating the substrate W. As a result, the photoresist film on the surface of the substrate W is removed by the SPM. At this time, since the surface of the photoresist film is ashed to some extent by pretreatment with an ozone gas, the photoresist film can be easily removed by a small amount of SPM even if the surface of the photoresist film is cured. After the treatment of the substrate W by the SPM is completed, the control unit 111 performs a cleaning treatment and a drying treatment with pure water.

### Step S8

The control unit 111 operates the center robot CR to transport the substrate W to the passing unit 19, and operates the indexer robot IR to carry the substrate W out to return it to the carrier C. By such a series of operations, removal treatment of the photoresist film on the substrate W is performed.

According to the present embodiment, since the control unit 111 closes the control valve 55 and opens the control valve 101 at the time of non-treatment with an ozone gas, an ozone gas having a treatment concentration generated by the ozone gas supply unit 11 is discharged from the auxiliary pipe 97 to the exhaust main pipe 33 without being supplied to the chamber 32. At the time of treatment with an ozone gas, the control unit 111 opens the control valve 101 while adjusting the flow rate by the control valve 55, so that an ozone gas is supplied to the substrate W held by the heat treatment plate 29 in the chamber 32 from the ozone gas supply unit 11 that constantly generates an ozone gas having a treatment concentration through the flow pipe 53. Therefore, since there is no waiting time for the treatment with an ozone gas, the treatment time with an ozone gas can be shortened, and the throughput can be improved.

The present invention is not limited to the above embodiment, and can be modified as follows.
(1) In the above-described embodiment, the substrate treatment apparatus 1 including the four chambers 32 and the four flow pipes 53 has been described as an example. However, the present invention does not necessarily include the plurality of chambers 32 and the plurality of flow pipes 53. That is, the present invention can be applied to the substrate treatment apparatus 1 including one chamber 32 and one flow pipe 53.
(2) In the above-described embodiment, the flow rate by the control valve 101 is adjusted in conjunction with the flow rate by each control valve 55 and each mass flow controller 57 so that the difference ΔF between the flow rate of the first flow rate F1 and the flow rate of the second flow rate F2 falls within a predetermined value.

However, in the present invention, it is not essential to leave the reserve power related to the supply of the ozone gas by the predetermined value on the ozone gas supply unit 11 side as described above. Therefore, the maximum supply amount of the ozone gas supply unit 11 may be supplied to all the chambers 32.
(3) In the above-described embodiment, the ozone gas supply unit 11 includes the automatic pressure regulator 49, and the auxiliary pipe 97 includes the automatic pressure regulator 99, but this configuration is not essential in the present invention. That is, with these configurations, even with the configuration including the plurality of chambers 32, the treatment with the ozone gas can be stably performed. Therefore, in a case where the chamber 32 includes a single chamber or the number of chambers 32 which are sufficient with a supply amount which is significantly smaller in total than the maximum supply amount of the ozone gas supply unit 11, it is not necessary to have such a configuration.
(4) In the above-described embodiment, the substrate treatment apparatus 1 includes the ozone gas decomposition unit 13, but the present invention does not require the ozone gas decomposition unit 13.
(5) In the above-described embodiment, the substrate treatment apparatus 1 includes the SPM unit 23, but the present invention does not require the SPM unit 23.

For example, the substrate W processed by the ozone gas bake unit 21 may be processed by the SPM unit 23 included in another apparatus.
(6) In the above-described embodiment, the substrate treatment apparatus 1 includes the indexer block 3, the transport block 7, the carrier placing portion 17, the passing unit 19, and the like, and is configured to continuously transport a plurality of substrates W to perform treatment efficiently, but the present invention is not limited to such a configuration. That is, the present invention can also be applied to a substrate treatment apparatus that does not include a transfer system or the like and includes a configuration for performing treatment with an ozone gas having a predetermined treatment concentration.

### Third Embodiment

Next, a third embodiment of the present invention will be described with reference to the drawings.

Configurations common to the first embodiment described above are denoted by the same reference numerals, and a detailed description thereof will be omitted.

Correspondence relationship with each component in claims 12 to 16 of the present invention is as follows.

The SPM unit 23 corresponds to a “treatment liquid chamber”, and the center robot CR corresponds to a “transport mechanism”. The ozone gas supply unit 11 corresponds to an “ozone gas supply source”. The heat treatment plate 29 corresponds to a “holding mechanism”, the lower lid 25 corresponds to an “upper lid member”, and the upper lid 27 corresponds to a “lower lid member”. The supply pipe 53 corresponds to a “first pipe”, the control valve 55 corresponds to a “first control valve”, the inert gas supply pipe 65 corresponds to a “second pipe”, and the on-off valve 69 and the mass flow controller 67 correspond to a “third control valve”. The suction pipe 73 corresponds to an “auxiliary exhaust pipe”, and the control valve 74 corresponds to a “fourth control valve”. The exhaust pipe 77 corresponds to an “exhaust pipe” in the present invention.

The on-off valve 93 corresponds to a “second control valve”, the flow rate adjusting valve 83, the on-off valve 85, and the vacuum ejector 79 correspond to a “first exhaust unit”, the flow rate adjusting valve 89, the on-off valve 91, and the vacuum ejector 79 correspond to a “second exhaust unit”, and the flow rate adjusting valves 83 and 89, the on-off valves 85 and 91, and the vacuum ejector 79 correspond to an “exhaust mechanism”. The first flow rate Fa corresponds to a “first exhaust flow rate”, and the second flow rate Fb corresponds to a “second exhaust flow rate”.

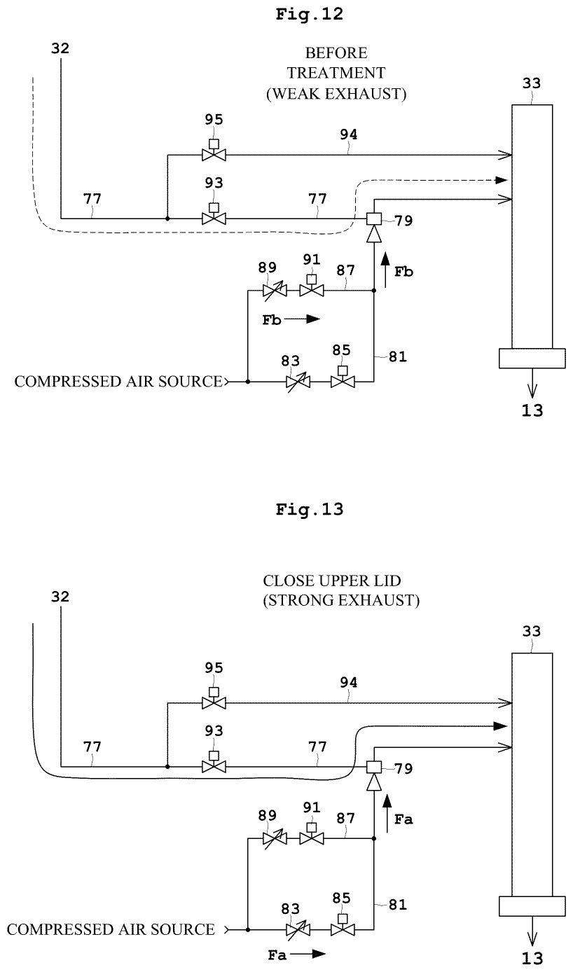

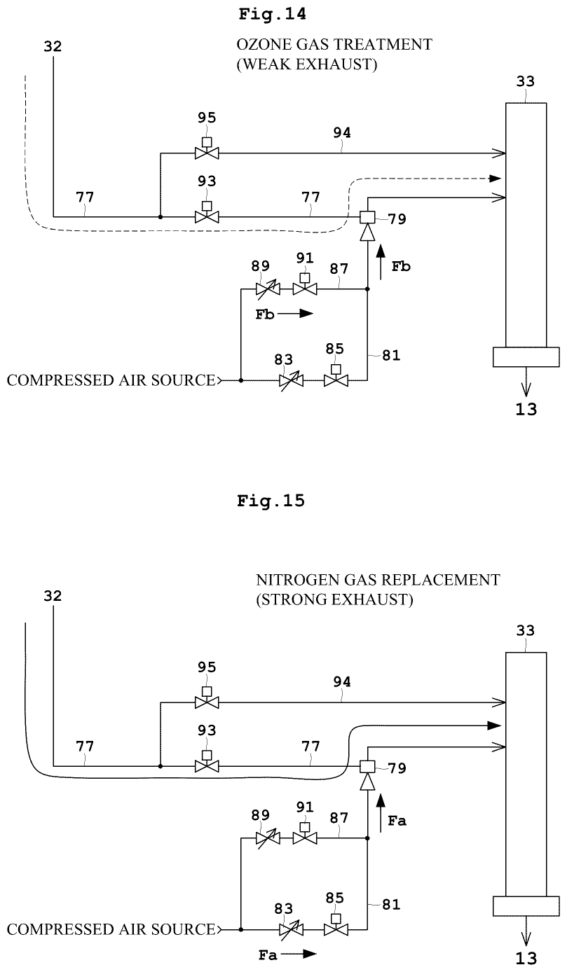

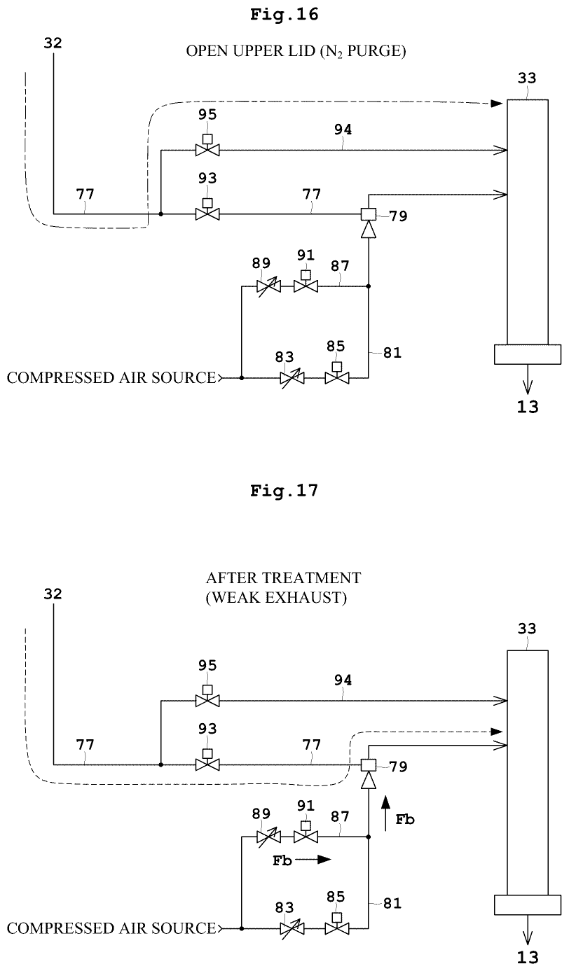

Here, treatment in the third embodiment will be described with reference to FIGS. 9 and 12 to 17. FIG. 12 is a schematic view for explaining weak exhaust before the treatment, FIG. 13 is a schematic view for explaining strong exhaust in a state where the upper lid is closed, FIG. 14 is a schematic view for explaining weak exhaust during the ozone gas treatment, FIG. 15 is a schematic view for explaining strong exhaust in replacement with nitrogen gas, FIG. 16 is a schematic view for explaining purge in the upper lid opening, and FIG. 17 is a schematic view for explaining weak exhaust after the treatment.

### Step S1

The operator activates the substrate treatment apparatus 1. In conjunction with this, the ozone gas supply unit 11 and the ozone gas decomposition unit 13 are also activated. Thus, under the control of the control unit 111, the ozone gas supply unit 11 starts generation of an ozone gas to be a treatment concentration. As shown in FIG. 5, it takes about 2 minutes to generate an ozone gas having a treatment concentration.

### Step S2

The control unit 111 monitors whether or not a predetermined time until an ozone gas having a treatment concentration is generated by the ozone gas supply unit 11 has elapsed, and proceeds to the next step S3 at the time point when the predetermined time has elapsed. Even before the concentration of the ozone gas reaches the treatment concentration, all the generated ozone gas is exhausted through the exhaust main pipe 33 via the auxiliary pipe 97 as in the non-treatment with the ozone gas shown in FIG. 7.

### Step S3

The operator gives instruction to start the process from a control console (not shown).

### Step S4

The substrate W to be processed accommodated in the carrier C is transported to the passing unit 19 via the indexer block 3, and is transported into the ozone gas bake unit 21 by the center robot CR. Note that before the process of transporting the substrate W into the chamber 32 in the next step S5, the control unit 111 operates the control valve 69 and the mass flow controller 67 to supply the nitrogen gas to the chamber 32. Furthermore, as shown in FIG. 12, the control unit 111 operates the vacuum ejector 79 by the flow rate adjusting valve 89 and the on-off valve 91. As a result, the inside of the chamber 32 is weakly exhausted, and the treatment space is kept clean with the inert gas.

### Step S5

When the substrate W is accommodated in the chamber 32, the control unit 111 moves the upper lid 27 to the lower lid 25 by the raising and lowering mechanism 31. As a result, the chamber 32 is sealed. At this time, the control unit 111 operates the flow rate adjusting valve 89 and the on-off valve 91 to stop the operation of the vacuum ejector 79 by the second drive pipe 81. Furthermore, as shown in FIG. 13, the control unit 111 operates the vacuum ejector 79 by the flow rate adjusting valve 83 and the on-off valve 85. The flow rate of the suction port of the vacuum ejector 79 is larger than the flow rate of the nitrogen gas supplied from the inert gas supply pipe 65. As a result, since the inside of the chamber 32 is strongly exhausted, the treatment space has a negative pressure. Therefore, the upper lid 27 is strongly brought into close contact with the lower lid 25, and the chamber 32 is completely sealed with respect to the periphery.

Thereafter, the controller 111 waits until the temperature of the substrate W placed on the heat treatment plate 29 rises to a predetermined temperature (for example, 100 to 300 °C). When the temperature of the substrate W reaches a predetermined temperature, the control unit 111 starts treatment with an ozone gas.

Specifically, the control unit 111 operates the mass flow controller 57 and the control valve 55 so that an ozone gas having a treatment concentration is supplied to the chamber 32 at a required flow rate. As a result, an ozone gas having a treatment concentration is supplied to the treatment space where the substrate W is placed. At this time, the controller 111 operates the flow rate adjusting valve 83 and the on-off valve 85 to stop the strong exhaust. Furthermore, as shown in FIG. 14, the control unit 111 operates the flow rate adjusting valve 89 and the on-off valve 91 to switch to weak exhaust. As a result, since the ozone gas having the treatment concentration stays in the treatment space, the treatment with the ozone gas can be sufficiently performed. When a predetermined ozone gas treatment time has elapsed, the control unit 111 operates the mass flow controller 57 and the control valve 55 to stop the supply of an ozone gas to the chamber 32.

Next, the control unit 111 replaces the ozone gas in the chamber 32 with nitrogen gas. Specifically, the control unit 111 operates the control valve 69 and the mass flow controller 67 to supply the nitrogen gas from the inert gas supply pipe 65 in FIG. 6 to the chamber 32. In addition, the control unit 111 operates the vacuum ejector 75, opens the control valve 74, and causes the suction pipe 73 to suck the second branch point 63. Furthermore, the control unit 111 operates the flow rate adjusting valve 89 and the on-off valve 91 to stop the weak exhaust. At the same time, as shown in FIG. 15, the control unit 111 operates the flow rate adjusting valve 83 and the on-off valve 85 to perform the strong exhaust. Since the inside of the chamber 32 is strongly exhausted, the ozone gas in the treatment space is efficiently replaced with the nitrogen gas. Therefore, the time required for replacement can be shortened. At this time, since the suction of the second branch point 63 is simultaneously performed, it is possible to prevent the ozone remaining in the filter 59 from being mixed into the treatment space. Therefore, the replacement efficiency with nitrogen gas can be improved. Furthermore, since the second branch point 63 is provided between the filter 59 and the mass flowmeter 57 and the control valve 55, it is possible to prevent particles that are likely to be generated in the mass flowmeter 57 and the control valve 55 from flowing into the treatment space. Therefore, the substrate W can be cleaned.

When the replacement with the nitrogen gas is completed, the control unit 111 operates the flow rate adjusting valve 83 and the on-off valve 85 to stop the strong exhaust. As shown in FIG. 16, the controller 111 opens the on-off valve 95. As a result, the inert gas is discharged only by the supply pressure through the purge pipe 94. At this time, since the chamber 32 has a positive pressure, the raising operation of the upper lid 25 by the raising and lowering mechanism 31 is smoothly performed. After the upper lid 25 is raised, the control unit 111 closes the on-off valve 95, and operates the flow rate adjusting valve 89 and the on-off valve 91 to perform weak exhaust as shown in FIG. 17. This keeps the treatment space clean with the inert gas. The controller 111 moves the substrate W to a cooling unit (not shown) to return the substrate W to room temperature.

### Step S6

The controller 111 operates the center robot CR to take out the substrate W from the ozone gas bake unit 21 and transport the substrate W to the SPM unit 23.

### Step S7

The control unit 111 supplies the SPM to the surface of the substrate W while heating the substrate W. As a result, the photoresist film on the surface of the substrate W is removed by the SPM. At this time, since the surface of the photoresist film is ashed to some extent by pretreatment with an ozone gas, the photoresist film can be easily removed by a small amount of SPM even if the surface of the photoresist film is cured. After the treatment of the substrate W by the SPM is completed, the control unit 111 performs a cleaning treatment and a drying treatment with pure water.

### Step S8

The control unit 111 operates the center robot CR to transport the substrate W to the passing unit 19, and operates the indexer robot IR to carry the substrate W out to return it to the carrier C. By such a series of operations, removal treatment of the photoresist film on the substrate W is performed.

According to the present embodiment, prior to supplying an ozone gas to the chamber 32 to perform ozone gas treatment, the control unit 111 opens the on-off valve 93, operates the flow rate adjusting valve 83 and the on-off valve 85 to operate the vacuum ejector 79, and strongly exhausts the inside of the chamber 32 to bring the upper lid 27 into close contact with the lower lid 25. When operating the control valve 55 to supply an ozone gas from the ozone gas supply unit 11 to the chamber 32, the control unit 111 stops strong exhaust and operates the flow rate adjusting valve 89 and the on-off valve 91 to operate the vacuum ejector 79 to weakly exhaust the chamber 32. Therefore, the degree of close contact between the upper lid 27 and the lower lid 25 is increased by strong exhaust until an ozone gas is supplied, and weak exhaust is performed at the time of supplying an ozone gas. Therefore, it is possible to suppress consumption of ozone gas while preventing leakage of ozone gas.

The present invention is not limited to the above embodiment, and can be modified as follows.
(1) In the above-described embodiment, the substrate treatment apparatus 1 including the four chambers 32 and the four flow pipes 53 has been described as an example. However, the present invention does not necessarily include the plurality of chambers 32 and the plurality of flow pipes 53. That is, the present invention can be applied to the substrate treatment apparatus 1 including one chamber 32 and one flow pipe 53.
(2) In the above-described embodiment, purge of supplying an inert gas to the chamber 32 is performed to make the inside of the chamber 32 have a positive pressure, and then the upper lid 27 is separated from the lower lid 25. However, the present invention does not require this configuration. Further, in the above-described embodiment, the inert gas supply pipe 65 for supplying an inert gas and the suction pipe 73 are provided, but the present invention does not necessarily include these.
(3) In the above-described embodiment, the exhaust flow rate in the exhaust pipe 77 is switched by switching the first drive pipe 81 and the second drive pipe 87 that supply compressed air to the vacuum ejector 79. However, the present invention does not require such a configuration. For example, one drive pipe, an on-off valve, and a mass flow controller may be provided, and the mass flow controller may be adjusted according to the exhaust flow rate. In the embodiment described above, the exhaust and suction are performed by the vacuum ejectors 75 and 79, but the present invention does not require such a configuration. For example, evacuation and suction may be performed by a vacuum pump.
(4) In the above-described embodiment, the substrate treatment apparatus 1 includes the ozone gas decomposition unit 13, but the present invention does not require the ozone gas decomposition unit 13.
(5) In the above-described embodiment, the substrate treatment apparatus 1 includes the SPM unit 23, but the present invention does not require the SPM unit 23.

For example, the substrate W processed by the ozone gas bake unit 21 may be processed by the SPM unit 23 included in another apparatus.
(6) In the above-described embodiment, the substrate treatment apparatus 1 includes the indexer block 3, the transport block 7, the carrier placing portion 17, the passing unit 19, and the like, and is configured to continuously transport a plurality of substrates W to perform treatment efficiently, but the present invention is not limited to such a configuration. That is, the present invention can also be applied to a substrate treatment apparatus that does not include a transfer system or the like and includes a configuration for performing treatment with an ozone gas having a treatment concentration.

### INDUSTRIAL APPLICABILITY

As described above, the present invention is suitable for a substrate treatment apparatus that performs predetermined treatment with an ozone gas on a substrate.

### REFERENCE SIGNS LIST

1 substrate treatment apparatus
W substrate
3 indexer block
5 treatment block
7 transport block
9 treatment liquid supply block
11 ozone gas supply unit
13 ozone gas decomposition unit
15 treatment unit
19 passing unit
TW1 to TW4 tower
21 ozone gas bake unit
23 SPM unit
25 lower lid
27 upper lid
29 heat treatment plate
31 raising and lowering mechanism
32 chamber
33 exhaust main pipe
35 supply pipe
41 generation pipe
43, 57, 67 mass flow controller
49, 99 automatic pressure regulator
51, 55, 69, 74, 101 control valve
53 flow pipe
59,71 filter
75, 79 vacuum ejector
61 first branch point
63 second branch point
65 inert gas supply pipe
73 suction pipe
77 exhaust pipe
81 first drive pipe
83,89 flow rate adjusting valve
85, 91 on-off valve
87 second drive pipe
94 purge pipe
Fa first flow rate
Fb second flow rate

1. A substrate treatment apparatus that performs treatment of removing a film applied to a substrate, the substrate treatment apparatus comprising:
a chamber that accommodates a substrate and forms a sealed treatment space;
a holder that holds the substrate in the chamber;
an ozone gas supply source that supplies an ozone gas having a treatment concentration for treating the substrate;
a first pipe that communicatively connects the chamber and the ozone gas supply source;
a first control valve that is provided in the first pipe and controls flow of ozone gas in the first pipe;
a first filter that is provided in the first pipe on a side closer to the chamber than the first control valve;
a second pipe having one end side communicatively connected to a first branch point connected to a side closer to the chamber than the first filter of the first pipe, and to which an inert gas is supplied from the other end side;
a second control valve that is provided in the second pipe and controls flow of the inert gas in the second pipe;
a suction pipe having one end side communicatively connected to a second branch point connected between the first filter of the first pipe and the first control valve, and which is sucked from the other end side; and
a controller that supplies an ozone gas into the chamber in a state where the first control valve is opened and the second control valve is closed to treat a substrate, and then closes the first control valve and opens the second control valve to cause suction by the suction pipe to be performed when the inert gas is supplied into the chamber.

2. The substrate treatment apparatus according to claim 1, wherein
the suction by the suction pipe is performed with a suction force with which supply of an inert gas supplied from the second pipe to the chamber is not hindered.

3. The substrate treatment apparatus according to claim 1, wherein
the suction pipe includes, on the other end side, a vacuum ejector that generates a suction force caused by supplying compressed gas.

4. The substrate treatment apparatus according to claim 1, wherein
the suction pipe controls a suction force at the second branch point and includes a suction control valve operated by the controller.

5. The substrate treatment apparatus according to claim 1, wherein
the second pipe includes a second filter between the first branch point and the second control valve.

6. The substrate treatment apparatus according to claim 1, further comprising:
a treatment liquid chamber that houses a substrate and performs treatment with a treatment liquid; and
a transport robot that transports the substrate, wherein
the substrate treated with an ozone gas in the chamber is transported to the treatment liquid chamber by the transport robot, and the substrate is processed with the treatment liquid in the treatment liquid chamber.

7. A substrate treatment apparatus that performs treatment of removing a film deposited to a substrate, the substrate treatment apparatus comprising:
a chamber that accommodates a substrate and forms a sealed treatment space;
a holder that holds the substrate in the chamber;
an ozone gas supply source that supplies an ozone gas for treating the substrate while constantly generating the ozone gas;
a supply pipe through which the ozone gas supplied from the ozone gas supply source flows;
a flow pipe that communicatively connects the supply pipe and the chamber;
a control valve that is provided in the flow pipe and controls flow of the ozone gas flowing through the flow pipe;
an auxiliary pipe that communicatively connects an exhaust port for discharging gas and the supply pipe and discharges the ozone gas supplied from the ozone gas supply source to the exhaust port;
an exhaust valve that is provided in the auxiliary pipe and adjusts a flow rate of the ozone gas flowing through the auxiliary pipe; and
a controller that closes the control valve to open the exhaust valve at the time of non-treatment, in which no ozone gas is supplied to the chamber, and causes the ozone gas supplied from the ozone gas supply source to be discharged to the exhaust port, and opens the control valve while adjusting the flow rate by the exhaust valve at the time of treatment in which an ozone gas is supplied to the chamber and a substrate held by the holder is processed with the ozone gas.

8. The substrate treatment apparatus according to claim 7, wherein
a plurality of the chambers are provided,
a plurality of the flow pipes are provided,
each of the flow pipes branches from the supply pipe and is communicatively connected to each of the chambers,
the control valve is provided in each of the plurality of flow pipes, and
at the time of the treatment, at least one of the plurality of chambers is in a state of supplying an ozone gas.

9. The substrate treatment apparatus according to claim 8, wherein
the controller adjusts the flow rate by the exhaust valve in conjunction with the flow rate by each of the control valves so that a difference between a first flow rate that is a flow rate of the ozone gas flowing through the supply pipe and a second flow rate that is a total flow rate of the ozone gas flowing through each of the flow pipes falls within a predetermined value during the treatment.

10. The substrate treatment apparatus according to claim 8, wherein
the ozone gas supply source includes a first on-off valve that allows or blocks flow of ozone gas to the supply pipe, and a first pressure adjustment mechanism that maintains a pressure of ozone gas in the supply pipe at a first pressure, and
the auxiliary pipe includes, as the exhaust valve, a second on-off valve that allows or blocks flow of ozone gas discharged to the exhaust port, and a second pressure adjustment mechanism that maintains a pressure of ozone gas in the auxiliary pipe at a second pressure smaller than the first pressure.

11. The substrate treatment apparatus according to claim 7, further comprising:
a treatment liquid chamber that accommodates a substrate and performs treatment with a treatment liquid; and
a transport robot that transports the substrate, wherein
the substrate treated with an ozone gas in the chamber is transported to the treatment liquid chamber by the transport robot, and the substrate is processed with a treatment liquid in the treatment liquid chamber.

12. A substrate treatment apparatus that performs treatment of removing a film deposited on a substrate, the substrate treatment apparatus comprising:
a chamber including a lower lid member that supports a holder that holds the substrate at a lower portion, an upper lid member that abuts on the lower lid member from above to form a treatment space, and a raising and lowering mechanism that lowers the upper lid member with respect to the lower lid member when the substrate is processed and raises the upper lid member from the lower lid member when the substrate is not processed;
an ozone gas supply source that supplies an ozone gas having a treatment concentration for treating the substrate;
a first pipe that communicably connects the ozone gas supply source and the chamber;
a first control valve that is provided on the first pipe and controls flow of ozone gas flowing through the first pipe;
an exhaust pipe that is communicably connected to the chamber and discharges gas in the treatment space to an exhaust port outside the apparatus;
a second control valve that is provided in the exhaust pipe and controls exhaust in the exhaust pipe;
an exhaust mechanism including a first exhaust unit that is provided on the exhaust port side of the second control valve in the exhaust pipe and performs exhaust at a first exhaust flow rate, and a second exhaust unit that is provided on the exhaust port side of the second control valve in the exhaust pipe and performs exhaust at a second exhaust flow rate lower than the first exhaust flow rate; and
a controller that, prior to supplying an ozone gas from the ozone gas supply source to the chamber to perform ozone gas treatment, when opening the second control valve, operating the first exhaust unit, exhausting an inside of the chamber at a first exhaust flow rate to bring the upper lid member into close contact with the lower lid member, and operating the first control valve to supply an ozone gas from the ozone gas supply source to the chamber, stops the first exhaust unit and operates the second exhaust unit to exhaust the chamber at a second exhaust flow rate.

13. The substrate treatment apparatus according to claim 12, further comprising:
a second pipe having one end side communicatively connected to a first branch point of the first pipe and to which an inert gas is supplied from the other end side;
a third control valve that controls flow of the inert gas in the second pipe;
an auxiliary exhaust pipe having one end side communicatively connected to a second branch point of the exhaust pipe on the chamber side of the second control valve and the other end side communicatively connected to the exhaust port; and
a fourth control valve that is provided in the auxiliary exhaust pipe and controls flow of gas in the auxiliary exhaust pipe, wherein
after the ozone gas treatment, the controller operates the third control valve to supply the inert gas into the chamber, operates the first exhaust unit instead of the second exhaust unit to exhaust the chamber at a first exhaust flow rate, and replaces an ozone gas in the chamber with an inert gas, then stops the first exhaust unit and closes the second control valve, opens the fourth control valve, and then raises the upper lid member by the raising and lowering mechanism.

14. The substrate treatment apparatus according to claim 13, wherein
the controller raises the upper lid member, then closes the fourth control valve, opens the second control valve, and operates the second exhaust unit to exhaust the chamber at a second exhaust flow rate.

15. The substrate treatment apparatus according to claim 12, wherein
the first exhaust unit and the second exhaust unit include a vacuum ejector that performs exhaust by supplying compressed gas.

16. The substrate treatment apparatus according to claim 12, further comprising:
a treatment liquid chamber that accommodates a substrate and performs treatment with a treatment liquid; and
a transport robot that transports the substrate, wherein
the substrate treated with an ozone gas in the chamber is transported to the treatment liquid chamber by the transport robot, and the substrate is processed with a treatment liquid in the treatment liquid chamber.
